(19) United States
(12) Patent Application Publication
(10) Pub. No.: US 2025/0098413 A1
(43) Pub. Date: Mar. 20, 2025

(54) DISPLAY DEVICE

(71) Applicant: Samsung Display Co., LTD., Yongin-si (KR)

(72) Inventor: Do Yeong PARK, Yongin-si (KR)

(21) Appl. No.: 18/886,579

(22) Filed: Sep. 16, 2024

(30) Foreign Application Priority Data
Sep. 19, 2023 (KR) 10-2023-0124929

(51) Int. Cl. H10K 59/121; H10K 59/122; H10K 59/131

(52) U.S. Cl. CPC H10K 59/121; H10K 59/122; H10K 59/131

(57) ABSTRACT

A display device including: a first pixel including a first light emitting area at which first light emitting elements are located; a second pixel spaced from the first light emitting area in a second direction and including a second light emitting area at which second light emitting elements are located; and a bank partitioning the first light emitting area and the second light emitting area, wherein the first pixel includes first to third alignment electrodes overlapping the first light emitting area and are sequentially located and spaced from each other in a first direction; and fourth to sixth alignment electrodes that are spaced from the first to third alignment electrodes in the second direction, and are sequentially located and spaced from each other in the first direction, and the fourth to sixth alignment electrodes extend in the second direction in the first light emitting area.

### CROSS-REFERENCE TO RELATED APPLICATION

This application claims priority to and the benefit of Korean Patent Application No. 10-2023-0124929 filed in the Korean Intellectual Property Office on Sep. 19, 2023, the entire content of which is incorporated by reference herein.

### BACKGROUND

### 1. Field

The present disclosure relates to a display device.

### 2. Description of the Related Art

Recently, as interest in an information display is increasing, research and development for display devices are continuously conducted.

### SUMMARY

Aspects and features of embodiments of the present disclosure are to provide a display device that minimizes (e.g., improves) a decrease in luminous efficiency as a light emitting element disposed between alignment electrodes is biased toward one side of the alignment electrodes.

Aspects and features of embodiments of the present disclosure are not limited to the above-described aspects and features, and may be variously extended without departing from the spirit and scope of the present disclosure.

One or more embodiments of the present disclosure provide a display device including: a first pixel including a first light emitting area at which first light emitting elements are located; a second pixel spaced from the first light emitting area in a second direction and including a second light emitting area at which second light emitting elements are located; and a bank partitioning the first light emitting area and the second light emitting area, wherein the first pixel includes a first alignment electrode, a second alignment electrode, and a third alignment electrode overlapping the first light emitting area and are sequentially located and spaced from each other in a first direction; and a fourth alignment electrode, a fifth alignment electrode, and a sixth alignment electrode that are spaced from the first to third alignment electrodes in the second direction, and are sequentially located and spaced from each other in the first direction, and the fourth to sixth alignment electrodes extend in the second direction in the first light emitting area overlapping the second light emitting area.

The display device may further include a first bank pattern including a first opening exposing the first to third alignment electrodes; and a second bank pattern that is spaced from the first bank pattern in the second direction and includes a second opening exposing the fourth to sixth alignment electrodes.

The second bank pattern may overlap one area of the first light emitting area and one area of the second light emitting area.

The first to sixth alignment electrodes may not overlap the first bank pattern and the second bank pattern.

The first light emitting elements may include a (1-1)-th light emitting element located between the first alignment electrode and the second alignment electrode; a (1-2)-th light emitting element located between the fourth alignment electrode and the fifth alignment electrode; a (1-3)-the light emitting element located between the fifth alignment electrode and the sixth alignment electrode; and a (1-4)-th light emitting element located between the second alignment electrode and the third alignment electrode.

The first light emitting elements have been aligned in response to a first alignment signal supplied by the first alignment electrode, the third alignment electrode, and the fifth alignment electrode; the second alignment electrode and the fourth alignment electrode are configured to supply a second alignment signal; and the first alignment signal may be different from the second alignment signal.

A first end portion of the (1-1)-th light emitting element and a first end portion of the (1-4) light emitting element may be adjacent to the second alignment electrode, and a second end portion of the (1-2)-th light emitting element and a second end portion of the (1-3)-th light emitting element may be adjacent to the fifth alignment electrode.

The first pixel may include a first pixel electrode electrically connected to a first driving power source and the first end portion of the (1-1)-th light emitting element; a second pixel electrode spaced from the first pixel electrode and electrically connected to a second driving power source and a second end portion facing the first end portion of the (1-4)-th light emitting element; and connection electrodes electrically connecting the first pixel electrode and the second pixel electrode.

The connection electrodes may include a first connection electrode electrically connected to a second end portion of the (1-1)-th light emitting element and a first end portion of the (1-2)-th light emitting element; a second connection electrode electrically connected to a second end portion of the (1-2)-th light emitting element and a first end portion of the (1-3)-th light emitting element; and a third connection electrode electrically connected to a second end portion of the (1-3)-th light emitting element and a first end portion of the (1-4)-th light emitting element.

The first connection electrode and the third connection electrode may extend in the second direction from the first opening of the first bank pattern to the second opening of the second bank pattern.

The second connection electrode may not overlap the first bank pattern and the second bank pattern.

The second connection electrode may overlap the fifth alignment electrode and the sixth alignment electrode in a plan view.

The first pixel electrode and the second pixel electrode may extend between the first bank pattern and the second bank pattern in the first opening.

The first pixel may include a first contact portion and a second contact portion located between the first bank pattern and the second bank pattern within the first light emitting area; the first pixel electrode may be electrically connected to the first driving power source through the first contact portion; and the second pixel electrode may be electrically connected to the second driving power source through the second contact portion.

The bank may include a first vertical extension and a second vertical extension that are spaced from each other in the first direction and extend in the second direction; and a first horizontal extension and a second horizontal extension that are spaced from each other in the second direction and extend in the first direction, and the first light emitting area may correspond to an area in which the first vertical extension, the second vertical extension, the first horizontal extension, and the second horizontal extension cross each other.

Portions of the first to third alignment electrodes may overlap the first horizontal extension in a plan view, and portions of the fourth to sixth alignment electrodes may overlap the second horizontal extension in a plan view.

Another embodiment of the present disclosure provides a display device including: a first pixel including a first light emitting area at which first light emitting elements are located; a second pixel spaced from the first light emitting area in a second direction and including a second light emitting area at which second light emitting elements are located; a bank partitioning the first light emitting area and the second light emitting area; a first alignment electrode, a second alignment electrode, a third alignment electrode, a fourth alignment electrode, a fifth alignment electrode, and a sixth alignment electrode that are sequentially located and spaced from each other in a first direction; and a seventh alignment electrode, an eighth alignment electrode, a ninth alignment electrode, a tenth alignment electrode, an eleventh alignment electrode, and a twelfth alignment electrode that are spaced from the first to sixth alignment electrodes in the second direction, and are sequentially located and spaced from each other in the first direction, wherein the eighth to eleventh alignment electrodes extend in the second direction in the first light emitting area overlapping the second light emitting area.

The first light emitting elements may include a (1-1)-th light emitting element located between the eighth alignment electrode and the ninth alignment electrode; a (1-2)-th light emitting element located between the second alignment electrode and the third alignment electrode; a (1-3)-th light emitting element located between the fourth alignment electrode and the fifth alignment electrode; and a (1-4)-th light emitting element located between the tenth alignment electrode and the eleventh alignment electrode.

The display device may further include a first bank pattern including a first opening exposing the first to sixth alignment electrodes; and a second bank pattern that is spaced from the first bank pattern in the second direction and includes a second opening exposing the seventh to twelfth alignment electrodes.

The first opening may include a (1-1)-th opening exposing the first to third alignment electrodes and a (1-2)-th opening spaced from the (1-1)-th opening in the first direction and exposing the fourth to sixth alignment electrodes, and the second opening may include a (2-1)-th opening exposing the seventh to ninth alignment electrodes and a (2-2)-th opening spaced from the (2-1)-th opening in the first direction and exposing the tenth to twelfth alignment electrodes.

The display device according to the embodiments of the present disclosure allows an alignment signal applied to alignment electrodes disposed at an upper portion to be different from an alignment signal applied to alignment electrodes disposed at a lower portion within a light emitting area of a pixel, so that an alignment direction of light emitting elements disposed between the alignment electrodes disposed at the upper portion may be opposite to an alignment direction of light emitting elements disposed between the alignment electrodes disposed at the lower portion. Accordingly, a pixel electrode disposed on a light emitting element is disposed according to a position of a light emitting element that is biased to one side of the alignment electrodes, so that it is possible to apply a signal to the light emitting element and simultaneously minimize (e.g., improve) contact defects caused by the biased light emitting element.

However, the effects, aspects, and features of embodiments of the present disclosure are not limited to the above-described effects, and may be variously extended without departing from the spirit and scope of the present disclosure.

### BRIEF DESCRIPTION OF DRAWINGS

FIG. 1 illustrates a schematic plan view of a display device according to one or more embodiments of the present disclosure.

FIG. 2 illustrates a circuit diagram of an embodiment of a sub-pixel included in the display device of FIG. 1.

FIG. 3 illustrates a schematic perspective cutaway view of a light emitting element included in the sub-pixel of FIG. 2.

FIG. 4 illustrates a schematic cross-sectional view of an embodiment of a light emitting element of FIG. 2.

FIG. 5A illustrates a schematic top plan view of a bank for partitioning pixels included in the display device of FIG. 1.

FIG. 5B illustrates a schematic top plan view of an embodiment of a bank pattern defining an area in which alignment electrodes for aligning light emitting elements of FIG. 2 are exposed.

FIG. 6 illustrates a schematic top plan view of an embodiment of a disposition relationship between the bank of FIG. 5A and the bank pattern of FIG. 5B.

FIG. 7 illustrates a schematic top plan view of an embodiment of alignment electrodes and light emitting elements disposed within an opening defined by the bank pattern of FIG. 6.

FIG. 8 illustrates a schematic top plan view of another embodiment of alignment electrodes and light emitting elements disposed within an opening defined by the bank pattern of FIG. 6.

FIG. 9 illustrates a schematic top plan view of another embodiment of alignment electrodes and light emitting elements disposed within an opening defined by the bank pattern of FIG. 6.

FIG. 10 illustrates a schematic top plan view of an embodiment of a sub-pixel included in the display device of FIG. 1.

FIG. 11 illustrates a schematic cross-sectional view of an example taken along the line A-A′ of FIG. 10.

FIG. 12 illustrates a schematic top plan view of another embodiment of a disposition relationship between the bank of FIG. 5A and the bank pattern of FIG. 5B.

FIG. 13 illustrates a schematic top plan view of an embodiment of alignment electrodes and light emitting elements disposed within an opening defined by the bank pattern of FIG. 12.

FIG. 14 illustrates a schematic top plan view of another embodiment of a sub-pixel included in the display device of FIG. 1.

### DETAILED DESCRIPTION

Hereinafter, one or more embodiments of the present disclosure will be described in detail with reference to the accompanying drawings. The same reference numerals are used for the same constituent elements on the drawings, and duplicate descriptions for the same constituent elements are omitted.

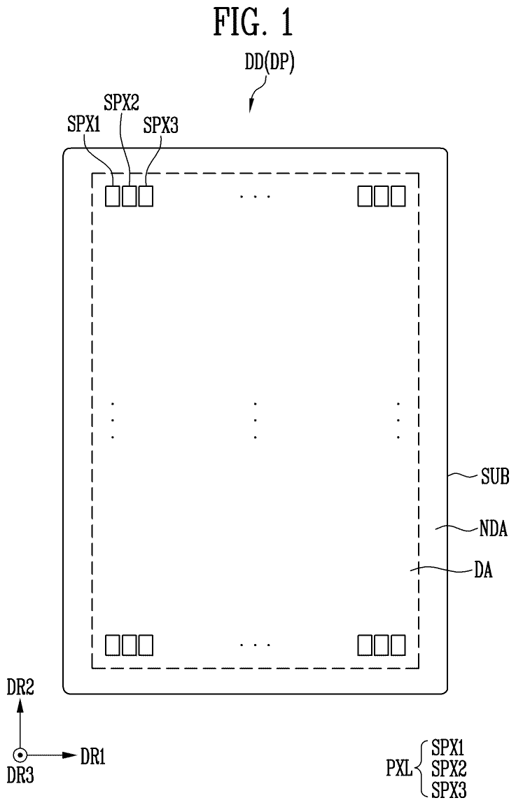

FIG. 1 illustrates a schematic plan view of a display device according to one or more embodiments of the present disclosure.

FIG. 1 briefly illustrates a structure of a display panel DP based on a display area DA. However, in one or more embodiments, at least one driving circuit portion (for example, at least one of a scan driver and a data driver), wires, and/or pads, may be further disposed in the display panel DP.

When the display device DD is one in which a display surface is applied to at least one surface thereof such as a smart phone, a television, a tablet PC, a mobile phone, an image phone, an electron book reader, a desktop PC, a laptop PC, a netbook computer, a workstation, a server, a PDA, a portable multimedia player (PMP), an MP3 player, a medical device, a camera, and/or a wearable device, the present disclosure may be applied thereto.

Referring to FIG. 1, the display panel DP may include a substrate SUB (or a base layer) and a plurality of pixels PXL provided on the substrate SUB.

The display panel DP may have various shapes. For example, the display panel DP may be provided in a rectangular plate shape, but is not limited thereto. For example, the display panel DP may have a shape such as a circle or an ellipse. In addition, the display panel DP may include an angled corner and/or curved line type corner. For convenience, FIG. 1 illustrates that the display panel DP has a rectangular plate shape. In addition, in FIG. 1, an extending direction of a short side (for example, horizontal direction) of the display panel DP is indicated as a first direction DR1, and an extending direction of a long side (for example, vertical direction) is indicated as a second direction DR2.

The substrate SUB configures a base member of the display panel DP, and may be a rigid or flexible substrate or film. For example, the substrate SUB may be a hard substrate made of glass or tempered glass, a flexible substrate (or a thin film) made of a plastic and/or metallic material, and/or at least one layered insulating layer. The material and/or physical properties of the substrate SUB are not particularly limited.

The substrate SUB (and the display panel DP) may include a display area DA for displaying an image and a non-display area NDA excluding the display area DA, and disposed around the display area DA along one or more edges or a periphery of the display area DA. The display area DA may configure a screen on which an image is displayed, and when the non-display area NDA is disposed on at least one side of the display area DA, for example, the non-display area NDA may surround the display area DA, but is not limited thereto.

The pixel PXL may be disposed in the display area DA on the substrate SUB. The non-display area NDA may be disposed around the display area DA. In the non-display area NDA, various wires connected to the pixels PXL of the display area DA, pads, and/or an internal circuit may be disposed.

In describing one or more embodiments of the present disclosure, the term “connection (or coupling)” may comprehensively mean a physical and/or electrical connection (or coupling). In addition, this may comprehensively mean a direct or indirect connection (or coupling), and an integrated or non-integrated connection (or coupling).

The pixel PXL includes sub-pixels SPX1 to SPX3, and for example, the pixel PXL may include a first sub-pixel SPX1, a second sub-pixel SPX2, and a third sub-pixel SPX3.

Each of the sub-pixels SPX1 to SPX3 may be configured to emit light of a suitable color (e.g., a predetermined color). In one or more embodiments, the sub-pixels SPX1 to SPX3 may be configured to emit light of different colors. For example, the first sub-pixel SPX1 may be configured to emit light of a first color, the second sub-pixel SPX2 may be configured to emit light of a second color, and the third sub-pixel SPX3 may be configured to emit light of a third color. For example, the first pixel SPX1 may be a red pixel that is be configured to emit red light, the second pixel SPX2 may be a green pixel that is be configured to emit green light, and the third pixel SPX3 may be a blue pixel that is be configured to emit blue light, but the present disclosure is not limited thereto.

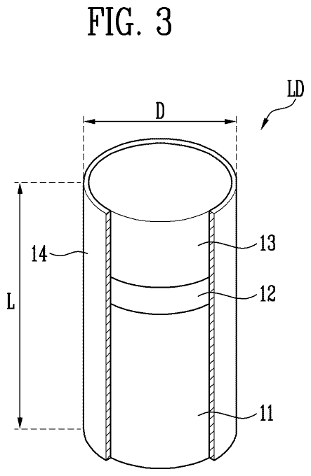

Each of the first to third sub-pixels SPX1 to SPX3 may include at least one light emitting element (for example, a light emitting element LD in FIG. 3) driven by a corresponding scan signal and data signal. The light emitting element may have a size as small as a nano-scale (or nano-meter) to a micro-scale (or micro-meter) and may be connected in parallel to light emitting elements disposed to be adjacent thereto, but is not limited thereto. The light emitting element may form a light source of each pixel PXL.

The first sub-pixel SPX1, the second sub-pixel SPX2, and the third sub-pixel PXL3 are provided with a first color light emitting element, a second color light emitting element, and a third color light emitting element as a light source, respectively, so that they are configured to respectively emit light of the first color, second color, and third color. In one or more embodiments, the first sub-pixel SPX1, the second sub-pixel SPX2, and the third sub-pixel SPX3 are provided with light emitting elements of the same color, and include color conversion layers and/or color filters of different colors disposed on respective light emitting elements, so that they may emit light of the first color, the second color, and the third color, respectively. However, the color, type, and/or number of the sub-pixels SPX1 to SPX3 configuring each pixel PXL are not particularly limited. That is, the color of light emitted by each pixel PXL may be variously changed.

The first to third sub-pixels SPX1 to SPX3 may be regularly arranged according to a stripe or PENTILE® arrangement structure. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. For example, the first, second, and third sub-pixels SPX1, SPX2, and SPX3 are sequentially and repeatedly disposed along the first direction DR1, and may also be repeatedly disposed along the second direction DR2. At least one of the first, second, and third sub-pixel SPX1, SPX2, and SPX3 disposed to be adjacent to each other may form one pixel PXL that may emit light of various colors. However, the arrangement structure of the sub-pixels SPX1 to SPX3 is not limited thereto, and the sub-pixels SPX1 to SPX3 may be arranged in the display area DA in various structures and/or methods.

In one or more embodiments, each of the sub-pixels SPX1 to SPX3 may be formed as an active pixel. For example, each of the sub-pixels SPX1 to SPX3 may include at least one light source (for example, a light emitting element) driven by a suitable control signal (e.g., a predetermined control signal, for example, a scan signal and/or a data signal) and/or a suitable power source (e.g., a predetermined power source, for example, a first power source and/or a second power source). However, the type, structure, and/or driving method of the sub-pixels SPX1 to SPX3 that may be applied to the display device are not particularly limited.

Hereinafter, the first sub-pixel SPX1, the second sub-pixel SPX2, and the third sub-pixel SPX3 are collectively referred to as a sub-pixel SPX.

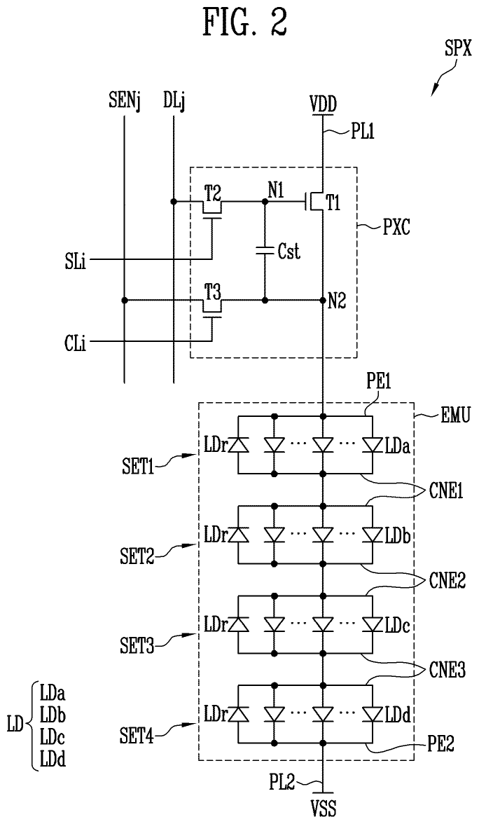

FIG. 2 illustrates a circuit diagram of an embodiment of a sub-pixel included in the display device of FIG. 1.

The sub-pixel SPX illustrated in FIG. 2 may be one of the sub-pixels SPX1 to SPX3 illustrated in FIG. 1, and the sub-pixels SPX1 to SPX3 arranged in each display area DA may be configured to be substantially the same as or similar to each other. For example, FIG. 2 illustrates to an electrical connection relationship between constituent elements included in the sub-pixel SPX applicable to an active matrix type of a display device according to one or more embodiments. However, the connection relationship of the constituent elements of the sub-pixel SPX is not limited thereto.

The sub-pixel SPX may include a light emitting portion EMU (or a light emitting unit) that is configured to generate light of luminance corresponding to a data signal. In addition, the sub-pixel SPX may selectively further include a pixel circuit PXC for driving the light emitting portion EMU.

The light emitting portion EMU may include a plurality of light emitting elements LD connected in series/parallel connections between a first power line PL1 and a second power line PL2. The first power line PL1 may be connected to a first driving power source VDD to be applied with a voltage of the first driving power source VDD, and the second power line PL2 may be connected to a second driving power source VSS to be applied with a voltage of the second driving power source VSS.

For example, the light emitting portion EMU may include a first pixel electrode PE1 (or a first electrode) connected to the first power source VDD via the pixel circuit PXC and the first power line PL1, a second pixel electrode PE2 (or a second electrode) connected to the second power source VSS through the second power line PL2, and a plurality of light emitting elements LD connected in series/parallel connections in the same direction between the first and second electrodes PE1 and PE2. In one or more embodiments, the first pixel electrode PE1 may be an anode (or anode electrode), and the second pixel electrode PE2 may be a cathode (or cathode electrode).

Each of the light emitting elements LD included in the light emitting portion EMU may include a first end portion connected to the first driving power source VDD through the first pixel electrode PE1 and a second end portion connected to the second driving power source VSS through the second pixel electrode PE2. The first driving power source VDD and the second driving power source VSS may have different potentials. For example, the first driving power source VDD may be set as a high potential power source, and the second driving power source VSS may be set as a low potential power source. In this case, a potential difference between the first and second driving power sources VDD and VSS may be set to be equal to or higher than a threshold voltage of the light emitting elements LD during a light emitting period of each sub-pixel SPX.

As described above, respective light emitting elements LD connected in series/parallel connections in the same direction (for example, a forward direction) between the first pixel electrode PE1 and the second pixel electrode PE2 supplied with voltages of different power sources may form respective effective light source.

The light emitting elements LD of the light emitting portion EMU may be configured to emit light with luminance corresponding to a driving current supplied through the corresponding pixel circuit PXC. For example, during each frame period, the pixel circuit PXC may supply a driving current corresponding to a grayscale value of corresponding frame data of the pixel circuit PXC to the light emitting portion EMU. The driving current supplied to the light emitting portion EMU may be divided to flow in each of the light emitting elements LD. Accordingly, while each light emitting element LD is configured to emit light with a luminance corresponding to the current flowing therein, the light emitting portion EMU may emit light having a luminance corresponding to the driving current.

In the above-described embodiment, although the structure in which both end portions of the light emitting elements LD are connected to in the same direction between the first and second driving power sources VDD and VSS has been described, the present disclosure is not limited thereto. In one or more embodiments, the light emitting portion EMU may further include at least one ineffective light source, for example, a reverse light emitting element LDr, in addition to the light emitting elements LD forming respective effective light sources. The reverse light emitting element LDr is connected in parallel between the first and second pixel electrodes PE1 and PE2 together with the light emitting elements LD forming the effective light sources, but may be connected between the first and second pixel electrodes PE1 and PE2 in the opposite direction with respect to the light emitting elements LD. The reverse light emitting element LDr maintains an inactive state even when a suitable driving voltage (e.g., a predetermined driving voltage, for example, a driving voltage in the forward direction) is applied between the first and second pixel electrodes PE1 and PE2, thus a current does not substantially flow in the reverse light emitting element.

The pixel circuit PXC may be connected to a scan line SLi and a data line DLj of the sub-pixel SPX. In addition, the pixel circuit PXC may be connected to a control line CLi and a sensing line SENj of the sub-pixel SPX. For example, when the sub-pixel SPX is disposed to an i-th row and a j-th column of the display area DA, the pixel circuit PXC of the sub-pixel SPX may be connected to the i-th scan line SLi, the j-th data line DLj, the i-th control line CLi, and the j-th sensing line SENj of the display area DA. In one or more embodiments, the control line CLi may be connected to the scan line SLi, or may be the scan line SLi.

The pixel circuit PXC may include transistors T1 to T3 and a storage capacitor Cst (or a capacitor).

The first transistor T1 is a driving transistor for controlling a driving current applied to the light emitting portion EMU, and may be connected between the first driving power source VDD and the light emitting portion EMU. Specifically, a first terminal (or first transistor electrode) of the first transistor T1 may be electrically connected to the first driving power source VDD through the first power line PL1, a second terminal (or second transistor electrode) of the first transistor T1 may be electrically connected to a second node N2, and a gate electrode of the first transistor T1 may be electrically connected to a first node N1. The first transistor T1 may control an amount of the driving current applied to the light emitting portion EMU from the first driving power source VDD through the second node N2 according to a voltage applied to the first node N1. In one or more embodiments, the first terminal of the first transistor T1 may be a drain electrode, and the second terminal of the first transistor T1 may be a source electrode, but the present disclosure is not limited thereto. In one or more embodiments, the first terminal thereof may be a source electrode, and the second terminal thereof may be a drain electrode.

The second transistor T2 is a switching transistor that selects the sub-pixel SPX in response to a scan signal and activates the sub-pixel SPX, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 are different terminals, and for example, when the first terminal is a drain electrode, the second terminal may be a source electrode.

When a scan signal of a gate-on voltage (for example, a high level voltage) is supplied from the scan line SLi, the second transistor T2 may be turned on to electrically connect the data line DLj and the first node N1. The first node N1 is a point at which the second terminal of the second transistor T2 is connected to the gate electrode of the first transistor T1, and the second transistor T2 may transmit a data signal to the gate electrode of the first transistor T1.

A first terminal of the third transistor T3 may be connected to the sensing line SENj, a second terminal of the third transistor T3 may be connected to the second terminal of the first transistor T1 or the second node N2, and a gate electrode of the third transistor T3 may be connected to the control line CLi. An initialization power source may be applied to the sensing line SENj. The third transistor T3 is an initialization transistor capable of initializing the second node N2, and when a sensing control signal is supplied from the control line CLi, the third transistor T3 may be turned on to transmit a voltage of the initialization power source to the second node N2. Accordingly, a second storage electrode of the storage capacitor Cst electrically connected to the second node N2 may be initialized. In one or more embodiments, the third transistor T3 connects the first transistor T1 to the sensing line SENj, so that it may obtain a sensing signal through the sensing line SENj, and may detect a characteristic of the sub-pixel SPX in addition to a threshold voltage of the first transistor T1 by using the sensing signal. Information on the characteristic of the sub-pixel SPX may be used to convert image data so that a characteristic deviation between the sub-pixels SPX may be compensated.

The storage capacitor Cst may be formed between the first node N1 and the second node N2, or may be electrically connected between the first node N1 and the second node N2. The storage capacitor Cst is charged with a data voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

The light emitting portion EMU may be configured to include at least one serial stage including a plurality of the light emitting elements LD electrically connected in parallel to each other.

In one or more embodiments, the light emitting portion EMU may be configured in a series/parallel mixed structure. For example, as shown in FIG. 2, the light emitting portion EMU may be configured to include a first serial stage SET1, a second serial stage SET2, a third serial stage SET3, and a fourth serial stage SET4. The number of the serial stages included in the light emitting portion EMU may be variously changed, and for example, the light emitting portion EMU may include 1, 2, 3, or 5 or more serial stages.

The light emitting portion EMU may include the first serial stage SET1, the second serial stage SET2, the third serial stage SET3, and the fourth serial stage SET4 sequentially connected between the first driving power source VDD and the second driving power source VSS.

The first serial stage SET1 (or a first stage) includes a first pixel electrode PE1 and a first connection electrode CNE1, and it may include at least one (1-1)-th light emitting element LDa connected between the first pixel electrode PE1 and the first connection electrode CNE1. In addition, the first serial stage SET1 may further include a reverse direction light emitting element LDr connected to the (1-1)-th light emitting element LDa in an opposite direction between the first pixel electrode PE1 and the first connection electrode CNE1.

The second serial stage SET2 (or second stage) includes a first connection electrode CNE1 and a second connection electrode CNE2, and it may include at least one (1-2)-th light emitting element LDb connected between the first connection electrode CNE1 and the second connection electrode CNE2. In addition, the second serial stage SET2 may further include a reverse direction light emitting element LDr connected to the (1-2) light emitting element LDb in an opposite direction between the first connection electrode CNE1 and the second connection electrode CNE2.

The third serial stage SET3 (or third stage) includes a second connection electrode CNE2 and a third connection electrode CNE3, and it may include at least one (1-3)-th light emitting element LDc connected between the second connection electrode CNE2 and the third connection electrode CNE3. In addition, the third serial stage SET3 may further include a reverse direction light emitting element LDr connected to the (1-3)-th light emitting element LDc in an opposite direction between the second connection electrode CNE2 and the third connection electrode CNE3.

The fourth serial stage SET4 (or fourth stage) includes a third connection electrode CNE3 and a second pixel electrode PE2, and it may include at least one (1-4)-th light emitting element LDd connected between the third connection electrode CNE3 and the second pixel electrode PE2. In addition, the fourth serial stage SET4 may further include a reverse direction light emitting element LDr connected to the (1-4)-th light emitting element LDd in an opposite direction between the third connection electrode CNE3 and the second pixel electrode PE2.

As described above, the light emitting portion EMU of the sub-pixel SPX including the serial stages SET1 to SET4 (or the light emitting elements LD) connected in a series/parallel mixed structure may easily adjust a driving current and/or voltage condition according to an applied product specification.

Particularly, the light emitting portion EMU of the sub-pixel SPX including the serial stages SET1 to SET4 may reduce the driving current compared to the light emitting portion in which the light emitting elements LD are only connected in parallel. In other words, the light emitting portion EMU of the sub-pixel SPX including the serial stages SET1 to SET4 may emit light with higher luminance for the same driving current.

In addition, the light emitting portion EMU of the sub-pixel SPX including the serial stages SET1 to SET4 may reduce the driving voltage applied to both ends of the light emitting portion EMU compared to a light emitting portion with a structure in which the same number of light emitting elements LD are all connected in series.

In FIG. 2, all the transistors T1 to T3 included in the pixel circuit PXC are illustrated as N-type transistors, but the present disclosure is not limited thereto. For example, at least one of the transistors T1 to T3 may be changed to a p-type transistor.

In addition, the structure and driving method of the sub-pixel SPX may be variously changed. For example, the pixel circuit PXC may be configured as a pixel circuit having various structures and/or driving methods in addition to that of the embodiment shown in FIG. 2.

For example, the pixel circuit PXC may not include the third transistor T3. In addition, the pixel circuit PXC may further include other circuit elements such as a compensation transistor for compensating for a threshold voltage of the first transistor T1, an initialization transistor for initializing the voltage of the first node N1 and/or of the first pixel electrode PE1, a light emission control transistor for controlling a period in which a driving current is supplied to the light emitting portion EMU, and/or a boosting capacitor for boosting the voltage of the first node N1.

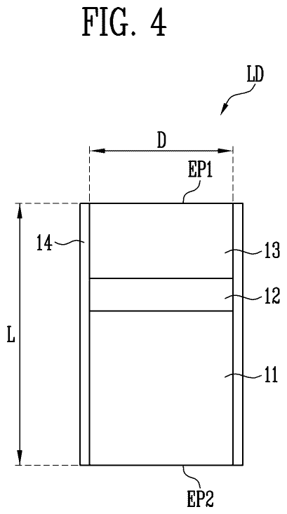

FIG. 3 illustrates a schematic perspective cutaway view of a light emitting element included in the sub-pixel of FIG. 2. FIG. 4 illustrates a schematic cross-sectional view of an example of a light emitting element of FIG. 2.

Referring to FIG. 3 and FIG. 4, the light emitting element LD may include a first semiconductor layer 11, a second semiconductor layer 13, and an active layer 12 interposed between the first and second semiconductor layers 11 and 13. For example, the light emitting element LD may be implemented as a stacked light emitting body (or a stacked pattern) in which the first semiconductor layer 11, the active layer 12, and the second semiconductor layer 13 are sequentially stacked.

The light emitting element LD may be provided to have a shape extending in one direction. When an extending direction of the light emitting element LD is a length direction, the light emitting element LD may include the first end portion EP1 and the second end portion EP2 along the length direction. One of the first semiconductor layer 11 and the second semiconductor layer 13 may be positioned at the first end portion EP1 of the light emitting element LD, and the other one of the first semiconductor layer 11 and the second semiconductor layer 13 may be positioned at the second end portion EP2 of the light emitting element LD.

The light emitting element LD may be provided in various shapes. As an example, the light emitting element LD may have a rod-like shape, bar-like shape, or pillar shape that is long (or an aspect ratio larger than 1) in a length direction as shown in FIGS. 3-4. As another example, the light emitting element LD may have a rod-like shape, bar-like shape, or pillar shape that is short (or an aspect ratio smaller than 1) in a length direction. As another example, the light emitting element LD may have a rod-like shape, bar-like shape, or pillar shape that has an aspect ratio of 1.

For example, the light emitting element LD may include a light emitting diode (LED) manufactured in an ultra-small size having a diameter D and/or a length L of nano scale (or nano meter) to micro scale (or micrometer).

When the light emitting element LD is long in a length direction (that is, an aspect ratio is larger than 1), the diameter D of the light emitting element LD may be about 0.5 μm to about 6 μm, and the length L thereof may be about 1 μm to about 10 μm. However, the diameter D and the length L of the light emitting element LD are not limited thereto, and the size of the light emitting element LD may be changed so that the light emitting element LD meets requirements (or design conditions) of a lighting device or a self-luminous display device to which the light emitting element LD is applied.

For example, the first semiconductor layer 11 may include at least one n-type semiconductor layer. The first semiconductor layer 11 may include an upper surface contacting the active layer 12 along the length direction of the light emitting element LD and a lower surface exposed to the outside. The lower surface of the first semiconductor layer 11 may be one end portion (or lower end portion, i.e. the second end portion EP2) of the light emitting element LD.

The active layer 12 is disposed on the first semiconductor layer 11, and may be formed to have a single or multi-quantum well structure. For example, when the active layer 12 is formed of a multi-quantum well structure, the active layer 12 may have a structure in which a barrier layer, a strain reinforcing layer, and a well layer, which consist of one unit, are periodically and repeatedly stacked. Because the strain reinforcing layer has a smaller lattice constant than that of the barrier layer, it may further reinforce strain applied to the well layer, for example, compressive strain. However, the structure of the active layer 12 is not limited to the above-described embodiment.

The active layer 12 may emit light having a wavelength of about 400 nm to 900 nm, and may have a double hetero-structure. The active layer 12 may include the first surface contacting the first semiconductor layer 11 and the second surface contacting the second semiconductor layer 13.

A color (e.g., a color of light) emitted by the light emitting element LD may be determined according to a wavelength of light emitted from the active layer 12. The color of the light emitting element LD may determine the color of the pixel corresponding thereto. For example, the light emitting element LD may emit red light, green light, or blue light.

When an electric field of a suitable voltage (e.g., a predetermined voltage) or more is applied to respective end portions of the light emitting element LD, the light emitting element LD emits light while electron-hole pairs are combined in the active layer 12. By controlling the light emission of the light emitting element LD by using this principle, the light emitting element LD may be used as a light source (or light emitting source) for various light emitting devices in addition to pixels of a display device.

The second semiconductor layer 13 is disposed on the second surface of the active layer 12, and may include a semiconductor layer of a type (e.g., or kind) different from that of the first semiconductor layer 11. For example, the second semiconductor layer 13 may include at least one p-type semiconductor layer.

The second semiconductor layer 13 may include a lower surface contacting the second surface of the active layer 12 along the length direction of the light emitting element LD and an upper surface exposed to the outside. Here, the upper surface of the second semiconductor layer 13 may be the other end portion (or upper end portion or the first end portion EP1) of the light emitting element LD.

The first semiconductor layer 11 and the second semiconductor layer 13 may have different thicknesses from each other in the length direction of the light emitting element LD. For example, the first semiconductor layer 11 may have a relatively greater thickness than that of the second semiconductor layer 13 along the length direction of the light emitting element LD. Accordingly, the active layer 12 of the light emitting element LD may be disposed to be closer to the upper surface of the second semiconductor layer 13 than the lower surface of the first semiconductor layer 11.

It is illustrated that each of the first semiconductor layer 11 and the second semiconductor layer 13 is formed as one layer, but the present disclosure is not limited thereto. In an example, each of the first semiconductor layer 11 and the second semiconductor layer 13 may further include at least one or more layers, for example, a cladding layer and/or a tensile strain barrier reducing (TSBR) layer according to the material of the active layer 12. The TSBR layer may be a strain reducing layer disposed between semiconductor layers having different lattice structures and serving as a buffer to reduce a difference in lattice constant. The TSBR layer may be formed of a p-type semiconductor layer such as p-GaInP, p-AlInP, or p-AlGaInP, but is not limited thereto.

The light emitting element LD may further include a contact electrode (hereinafter referred to as a “first contact electrode”) disposed on the second semiconductor layer 13 in addition to the first semiconductor layer 11, the active layer 12, and second semiconductor layer 13 described above. In addition, in one or more embodiments, another contact electrode (hereinafter referred to as a “second contact electrode”) disposed on one end of the first semiconductor layer 11 may be further included.

Each of the first and second contact electrode electrodes may be an ohmic contact electrode, but is not limited thereto. In one or more embodiments, the first and second contact electrodes may be a Schottky contact electrode. The first and second contact electrodes may include a conductive material.

The light emitting element LD may further include an insulating film 14 (or an insulating film). However, in one or more embodiments, the insulating film 14 may be omitted, or it may be provided so as to cover only some of the first semiconductor layer 11, the active layer 12, and the second semiconductor layer 13.

The insulating film 14 may prevent an electrical short circuit that may occur when the active layer 12 contacts conductive materials other than the first and second semiconductor layers 11 and 13. In addition, the insulating film 14 may reduce or minimize surface defects of the light emitting element LD to improve lifespan and luminous efficiency of the light emitting element LD. As long as the active layer 12 may prevent a short circuit with an external conductive material from being caused, whether or not the insulating film 14 is provided is not limited.

The insulating film 14 may be around (e.g., may surround) at least a portion of an outer surface (e.g., an outer peripheral or circumferential surface) of a light emitting stacked structure including the first semiconductor layer 11, the active layer 12, and the second semiconductor layer 13.

In the above-described embodiment, the structure in which the insulating film 14 entirely surrounds the outer surfaces (e.g., the outer peripheral or circumferential surfaces) of the first semiconductor layer 11, the active layer 12, and the second semiconductor layer 13 is described, but the present disclosure is not limited thereto.

The insulating film 14 may include a transparent insulating material. For example, the insulating film 14 may include at least one of insulating materials selected from among a silicon oxide (SiOx), a silicon nitride (SiNx), a silicon oxynitride (SiOxNy), an aluminum oxide (AlOx), a titanium oxide (TiOx), a hafnium oxide (HfOx), a titanium strontium oxide (SrTiOx), a cobalt oxide (CoxOy), a magnesium oxide (MgO), a zinc oxide (ZnOx), a ruthenium oxide (RuOx), a nickel oxide (NiO), a tungsten oxide (WOx), tantalum oxide (TaOx), a gadolinium oxide (GdOx), a zirconium oxide (ZrOx), a gallium oxide (GaOx), a vanadium oxide (VxOy), ZnO:Al, ZnO:B, InxOy:H, a niobium oxide (NbxOy), a fluorinated magnesium (MgFx), a fluorinated aluminum (AlFx), an alucone polymer film, a titanium nitride (TiN), a tantalum nitride (TaN), an aluminum nitride (AlNx), a gallium nitride (GaN), a tungsten nitride (WN), a hafnium nitride (HfN), a niobium nitride (NbN), gadolinium nitride (GdN), a zirconium nitride (ZrN), and/or a vanadium nitride (VN), but the present disclosure is not limited thereto, and various materials having insulating properties may be used as the material of the insulation film 14.

The insulating film 14 may be provided in a form of a single layer or in a form of a multilayer including a double layer.

The above-described light emitting element LD may be used as a light emitting source (or light source) for various display devices. The light emitting element LD may be manufactured through a surface treatment process. For example, when plurality of light emitting elements LD are mixed with a fluid solution (or a solvent) and supplied to each pixel area (for example, a light emitting area of each pixel or a light emitting area of each sub-pixel), each light emitting element LD may be surface-treated so that the light emitting elements LD may non-uniformly aggregated in the solution and may be uniformly sprayed.

A light emitting portion (or light emitting device) including the above-described light emitting elements LD may be used in various types of electronic devices that require a display device and a light source. For example, when a plurality of light emitting elements LD are disposed in a pixel area of each pixel of a display panel, the light emitting elements LD may be used as a light source of each pixel. However, an application field of the light emitting element LD is not limited to the above-described example. For example, the light emitting element LD may be used in other types of electronic devices that require a light source, such as a lighting device.

However, this is an example, and the light emitting element LD applied to the display device according to one or more embodiments of the present disclosure is not limited thereto. For example, the light emitting element may be a flip chip type micro light emitting diode or an organic light emitting element including an organic light emitting layer.

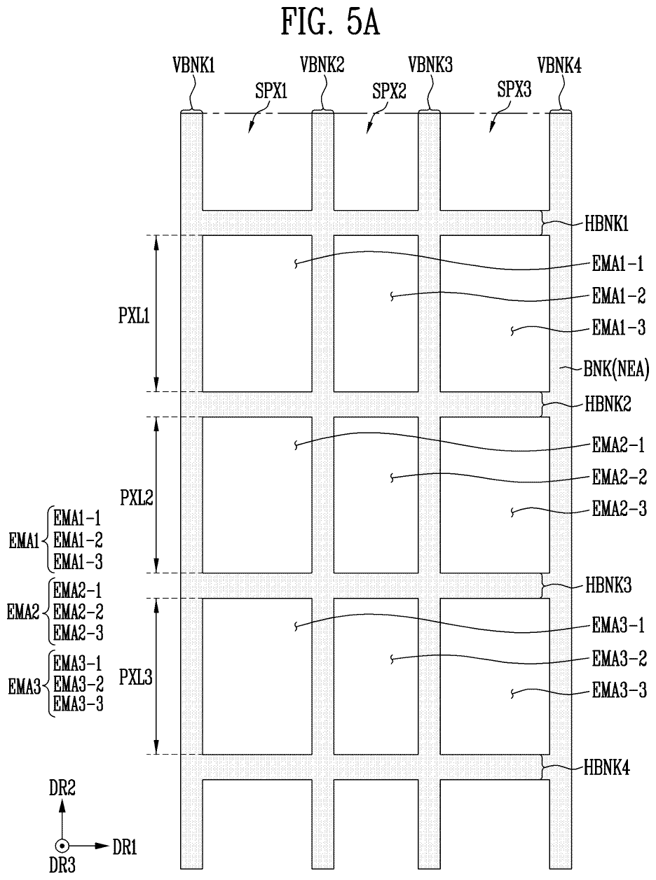

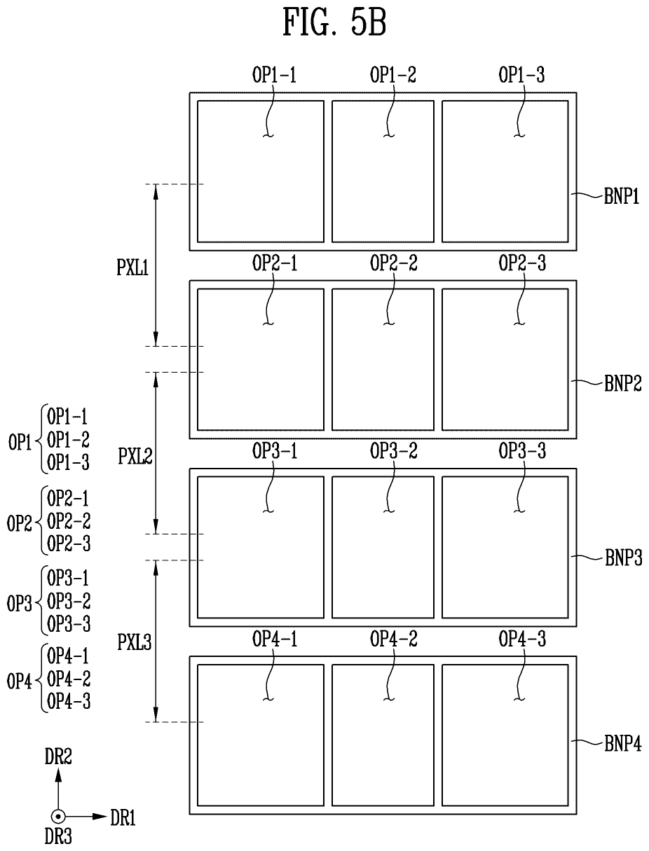

FIG. 5A illustrates a schematic top plan view of a bank for partitioning pixels included in the display device of FIG. 1.

FIG. 5A is a drawing for explaining light emitting areas EMA1, EMA2, and EMA3 and a non-light emitting area NEA of pixels PXL1 to PXL3, and mainly illustrates a bank BNK.

As shown in FIG. 5A, the bank BNK may partition the first to third pixels PXL1 to PXL3. Each of the first to third pixels PXL1 to PXL3 may include the first to third sub-pixels SPX1 to SPX3. That is, the bank BNK may partition the first to third sub-pixels SPX1 to SPX3.

In one or more embodiments, the first to third pixels PXL1 to PXL3 may be disposed to be spaced from each other in the second direction DR2. The first to third sub-pixels SPX1 to SPX3 included in each of the first to third pixels PXL1 to PXL3 may be disposed to be spaced from each other in the first direction DR1.

In one or more embodiments, the first pixel PXL1 may include the first light emitting area EMA1, the second pixel PXL2 may include the second light emitting area EMA2, and the third pixel PXL3 may include the third light emitting area EMA3. The first to third light emitting areas EMA1 to EMA3 may correspond to openings defined by the bank BNK.

In one or more embodiments, the first to third light emitting areas EMA1 to EMA3 may be sequentially disposed along the second direction DR2.

In one or more embodiments, the first light emitting area EMA1 may include a (1-1)-th light emitting area EMA1-1 corresponding to the first sub-pixel SPX1, a (1-2)-th light emitting area EMA1-2 corresponding to the second sub-pixel SPX2, and a (1-3)-th light emitting area EMA1-3 corresponding to the third sub-pixel SPX3. In an example, the (1-1)-th to (1-3)-th light emitting areas EMA1-1 to EMA1-3 may be sequentially disposed along the first direction DR1.

In one or more embodiments, the second light emitting area EMA2 may include a (2-1)-th light emitting area EMA2-1 corresponding to the first sub-pixel SPX1, a (2-2)-th light emitting area EMA2-2 corresponding to the second sub-pixel SPX2, and a (2-3)-th light emitting area EMA2-3 corresponding to the third sub-pixel SPX3. In an example, the (2-1)-th to (2-3)-th light emitting areas EMA2-1 to EMA2-3 may be sequentially disposed along the first direction DR1.

In one or more embodiments, the third light emitting area EMA3 may include a (3-1)-th light emitting area EMA3-1 corresponding to the first sub-pixel SPX1, a (3-2)-th light emitting area EMA3-2 corresponding to the second sub-pixel SPX2, and a (3-3)-th light emitting area EMA3-3 corresponding to the third sub-pixel SPX3. In one or more embodiments, the (3-1)-th to (3-3)-th light emitting areas EMA3-1 to EMA3-3 may be sequentially disposed along the first direction DR1.

In one or more embodiments, the non-light emitting area NEA may be an area substantially corresponding to the bank BNK. In a plan view, the bank BNK may be around (e.g., may surround) the first light emitting area EMA1, the second light emitting area EMA2, and the third light emitting area EMA3.

In one or more embodiments, the bank BNK may include first to fourth horizontal extensions HBNK1 to HBNK4 extending in the first direction DR1. The first to fourth horizontal extensions HBNK1 to HBNK4 may be spaced from each other in the second direction DR2 (for example, a vertical direction).

In one or more embodiments, first to fourth vertical extensions VBNK1 to VBNK4 extending in the second direction DR2 may be included. The first to fourth vertical extensions VBNK1 to VBNK4 may be spaced from each other in the first direction DR1 (for example, a horizontal direction).

In one or more embodiments, the first light emitting area EMA1 may be formed (e.g., may be defined) by the first and second horizontal extensions HBNK1 and HBNK2, and the first to fourth vertical extensions VBNK1 to VBNK4. In one or more embodiments, the (1-1)-th light emitting area EMA1-1 may be formed (e.g., may be defined) by the first and second horizontal extensions HBNK1 and HBNK2, and the first and second vertical extensions VBNK1 and VBNK2. The (1-2)-th light emitting area EMA1-2 may be formed (e.g., may be defined) by the first and second horizontal extensions HBNK1 and HBNK2, and the second and third vertical extensions VBNK2 and VBNK3. The (1-3)-th light emitting area EMA1-3 may be formed (e.g., may be defined) by the first and second horizontal extensions HBNK1 and HBNK2, and the third and fourth vertical extensions VBNK3 and VBNK4.

In one or more embodiments, the second light emitting area EMA2 may be formed (e.g., may be defined) by the second and third horizontal extensions HBNK2 and HBNK3 and the first to fourth vertical extensions VBNK1 to VBNK4. In one or more embodiments, the (2-1)-th light emitting area EMA2-1 may be formed (e.g., may be defined) by the second and third horizontal extensions HBNK2 and HBNK3, and the first and second vertical extensions VBNK1 and VBNK2. The (2-2)-th light emitting area EMA2-2 may be formed (e.g., may be defined) by the second and third horizontal extensions HBNK2 and HBNK3, and the second and third vertical extensions VBNK2 and VBNK3. The (2-3)-th light emitting area EMA2-3 may be formed (e.g., may be defined) by the second and third horizontal extensions HBNK2 and HBNK3, and the third and fourth vertical extensions VBNK3 and VBNK4.

In one or more embodiments, the third light emitting area EMA3 may be formed (e.g., may be defined) by the third and fourth horizontal extensions HBNK3 and HBNK4 and the first to fourth vertical extensions VBNK1 to VBNK4. In one or more embodiments, the (3-1)-th light emitting area EMA3-1 may be formed (e.g., may be defined) by the third and fourth horizontal extensions HBNK3 and HBNK4, and the first and second vertical extensions VBNK1 and VBNK2. The (3-2)-th light emitting area EMA3-2 may be formed (e.g., may be defined) by the third and fourth horizontal extensions HBNK3 and HBNK4, and the second and third vertical extensions VBNK2 and VBNK3. The (3-3)-th light emitting area EMA3-3 may be formed (e.g., may be defined) by the third and fourth horizontal extensions HBNK3 and HBNK4, and the third and fourth vertical extensions VBNK3 and VBNK4.

In one or more embodiments, the first light emitting area EMA1 may be disposed adjacent to the second light emitting area EMA2 with the second horizontal extension HBNK2 interposed therebetween. The second light emitting area EMA2 may be disposed adjacent to the third light emitting area EMA3 with the third horizontal extension HBNK3 interposed therebetween.

In one or more embodiments, the (1-1)-th light emitting area EMA1-1 may be disposed adjacent to the (1-2)-th light emitting area EMA1-2 with the second vertical extension VBNK2 interposed therebetween. The (1-2)-th light emitting area EMA1-2 may be disposed adjacent to the (1-3)-th light emitting area EMA1-3 with the third vertical extension VBNK3 interposed therebetween.

FIG. 5B illustrates a schematic top plan view of an embodiment of a bank pattern defining an area in which alignment electrodes for aligning light emitting elements of FIG. 2 are exposed.

FIG. 5B is a drawing for explaining first to fourth openings OP1 to OP4 in which alignment electrodes aligning light emitting elements (for example, the light emitting elements LD of FIG. 3 and FIG. 4) are exposed, and mainly illustrates bank patterns BNP1 to BNP4.

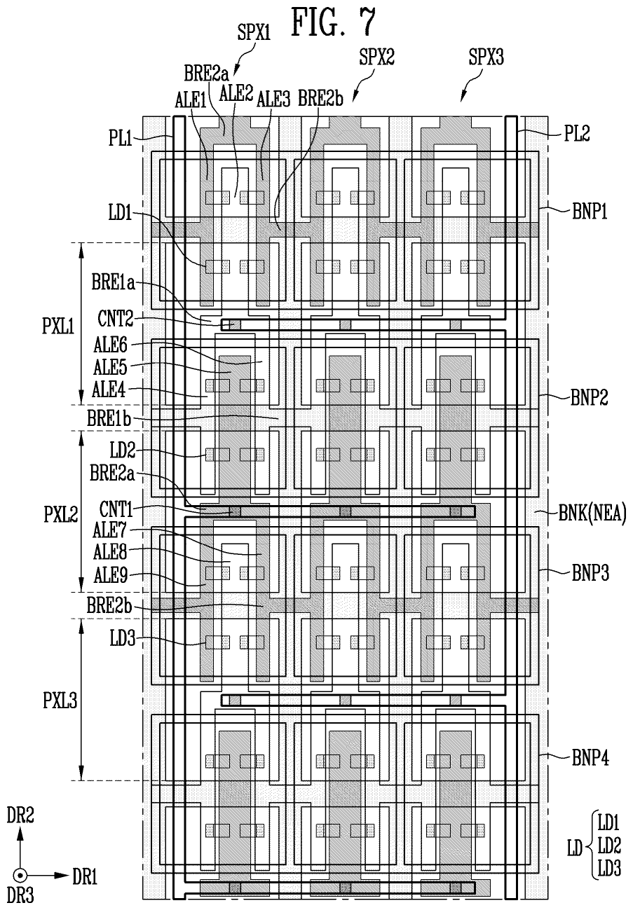

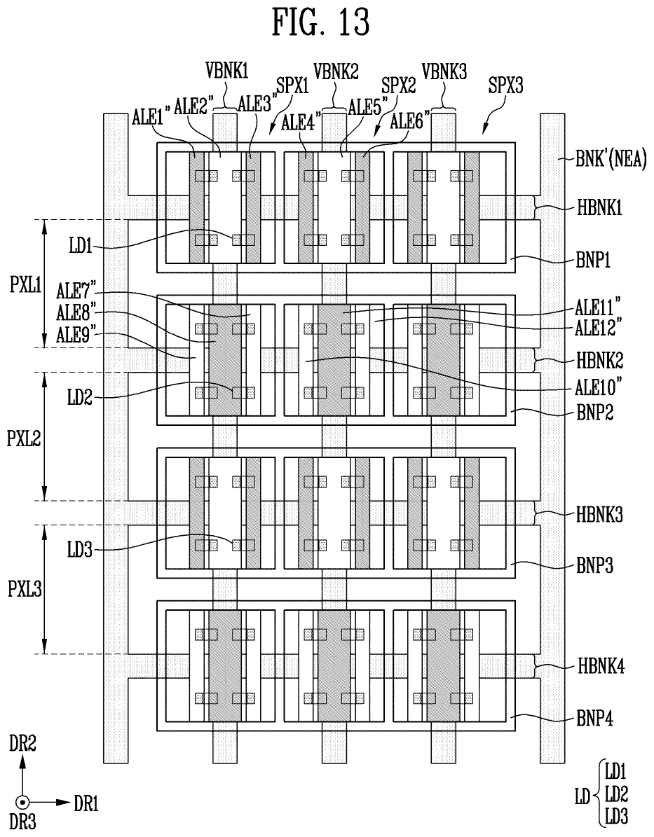

As shown in FIG. 5B, the bank patterns BNP1 to BNP4 may be sequentially disposed along the second direction DR2. In one or more embodiments, the first bank pattern BNP1, the second bank pattern BNP2, the third bank pattern BNP3, and the fourth bank pattern BNP4 may be sequentially disposed along the second direction DR2. The bank patterns BNP1 to BNP4 may include the openings OP1 to OP4. Alignment electrodes (for example, alignment electrodes ALE1 to ALE9 of FIG. 7 or first to twelfth alignment electrodes ALE1″ to ALE12″ of FIG. 13) may be exposed through the openings OP1 to OP4.

In one or more embodiments, the first bank pattern BNP1 may include the first opening OP1. The first opening OP1 may include a (1-1)-th opening OP1-1, a (1-2)-th opening OP1-2, and a (1-3)-th opening OP1-3. The (1-1)-th opening OP1-1, the (1-2)-th opening OP1-2, and the (1-3)-th opening OP1-3 may be disposed to be spaced from each other in the first direction DR1.

In one or more embodiments, the second bank pattern BNP2 may include the second opening OP2. The second opening OP2 may include a (2-1)-th opening OP2-1, a (2-2)-th opening OP2-2, and a (2-3)-th opening OP2-3. The (2-1)-the opening OP2-1, the (2-2)-th opening OP2-2, and the (2-3)-th opening OP2-3 may be disposed to be spaced from each other in the first direction DR1.

In one or more embodiments, the third bank pattern BNP3 may include the third opening OP3. The third opening OP3 may include a (3-1)-th opening OP3-1, a (3-2)-th opening OP3-2, and a (3-3)-th opening OP3-3. The (3-1)-th opening OP3-1, the (3-2)-th opening OP3-2, and the (3-3)-th opening OP3-3 may be disposed to be spaced from each other in the first direction DR1.

In one or more embodiments, the first pixel PXL1 may correspond to a lower end portion of the first opening OP1 and an upper end portion of the second opening OP2. In one or more embodiments, the second pixel PXL2 may correspond to a lower end portion of the second opening OP2 and an upper end portion of the third opening OP3. In one or more embodiments, the third pixel PXL3 may correspond to a lower end portion of the third opening OP3 and an upper end portion of the fourth opening OP4.

In one or more embodiments, the upper end portion of the second bank pattern BNP2 may correspond to the first pixel PXL1, and the lower end portion of the second bank pattern BNP2 may correspond to the second pixel PXL2. The first pixel PXL1 and the second pixel PXL2 may share alignment electrodes exposed through the second opening OP2 of the second bank pattern BNP2. In one or more embodiments, the upper end portion of the third bank pattern BNP3 may correspond to the second pixel PXL2, and the lower end portion of the third bank pattern BNP3 may correspond to the third pixel PXL3. The second pixel PXL2 and the third pixel PXL3 may share alignment electrodes exposed through the third opening OP3 of the third bank pattern BNP3.

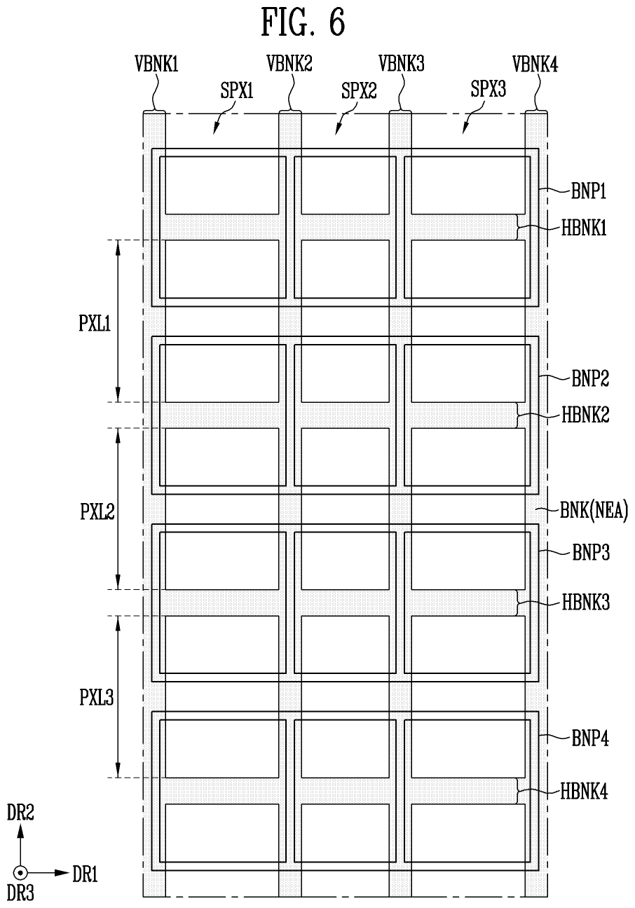

FIG. 6 illustrates a schematic top plan view of an embodiment of a disposition relationship between the bank of FIG. 5A and the bank pattern of FIG. 5B.

Referring to FIG. 5A, FIG. 5B, and FIG. 6, the bank BNK may overlap the bank patterns BNP1 to BNP4 in a plan view. In one or more embodiments, the first light emitting area EMA1 (for example, the light emitting area of the first pixel PXL1) of the bank BNK may overlap the lower end portion of the first bank pattern BNP1 and the upper end portion of the second bank pattern BNP2 in a plan view. In one or more embodiments, the second light emitting area EMA2 (for example, the light emitting area of the second pixel PXL2) of the bank BNK may overlap the lower end portion of the second bank pattern BNP2 and the upper end portion of the third bank pattern BNP3 in a plan view. In one or more embodiments, the third light emitting area EMA3 (for example, the light emitting area of the third pixel PXL3) of the bank BNK may overlap the lower end portion of the third bank pattern BNP3 and the upper end portion of the fourth bank pattern BNP4 in a plan view.

Referring to FIG. 5A, FIG. 5B, and FIG. 6, the (1-1)-th light emitting area EMA1-1, which is the light emitting area of the first sub-pixel SPX1 of the first pixel PXL1, may overlap the lower end portion of the (1-1)-th opening OP1-1 of the first bank pattern BNP1 and the upper end portion of the (2-1)-th opening OP2-1 of the second bank pattern BNP2, in a plan view. In one or more embodiments, the (1-2)-th light emitting area EMA1-2, which is the light emitting area of the second sub-pixel SPX2 of the first pixel PXL1, may overlap the lower end portion of the (1-2)-th opening OP1-2 of the first bank pattern BNP1 and the upper end portion of the (2-2)-th opening OP2-2 of the second bank pattern BNP2, in a plan view. In one or more embodiments, the (1-3)-th light emitting area EMA1-3, which is the light emitting area of the third sub-pixel SPX3 of the first pixel PXL1, may overlap the lower end portion of the (1-3)-th opening OP1-3 of the first bank pattern BNP1 and the upper end portion of the (2-3)-th opening OP2-3 of the second bank pattern BNP2, in a plan view.

In one or more embodiments, a boundary area between the (1-1)-th opening OP1-1 and the (1-2)-th opening OP1-2 may overlap the second vertical extension VBNK2 of the bank BNK. The boundary area between the (1-2)-th opening OP1-2 and the (1-3)-th opening OP1-3 may overlap the third vertical extension VBNK3 of the bank BNK.

In one or more embodiments, the first opening OP1 of the first bank pattern BNP1 may overlap the first horizontal extension HBNK1 of the bank BNK. In one or more embodiments, the first horizontal extension HBNK1 may be disposed across the (1-1)-th opening OP1-1, the (1-2)-th opening OP1-2, and the (1-3)-th opening OP1-3 of the first opening OP1.

In one or more embodiments, the second opening OP2 of the second bank pattern BNP2 may overlap the second horizontal extension HBNK2 of the bank BNK. In one or more embodiments, the second horizontal extension HBNK2 may be disposed across the (2-1)-th opening OP2-1, the (2-2)-th opening OP2-2, and the (2-3)-th opening OP2-3 of the second opening OP2.

In one or more embodiments, the third opening OP3 of the third bank pattern BNP3 may overlap the third horizontal extension HBNK3 of the bank BNK. In one or more embodiments, the third horizontal extension HBNK3 may be disposed across the (3-1)-th opening OP3-1, the (3-2)-th opening OP3-2, and the (3-3)-th opening OP3-3 of the third opening OP3.

In one or more embodiments, the fourth opening OP4 of the fourth bank pattern BNP4 may overlap the fourth horizontal extension HBNK4 of the bank BNK. In one or more embodiments, the fourth horizontal extension HBNK4 may be disposed across the (4-1)-th opening OP4-1, the (4-2)-th opening OP4-2, and the (4-3)-th opening OP4-3 of the fourth opening OP4.

In one or more embodiments, the second opening OP2 of the second bank pattern BNP2 may correspond to the lower end area of the first light emitting area EMA1 of the first pixel PXL1 and the upper end area of the second light emitting area EMA2 of the second pixel PXL2.

In one or more embodiments, the third opening OP3 of the third bank pattern BNP3 may correspond to the lower end area of the second light emitting area EMA2 of the second pixel PXL2 and the upper end area of the third light emitting area EMA3 of the third pixel PXL3.

In one or more embodiments, the fourth opening OP4 of the fourth bank pattern BNP4 may correspond to the lower end area of the third light emitting area EMA3 of the third pixel PXL3 and the upper end area of a light emitting area of a pixel adjacent to the third pixel PXL3 in the second direction DR2.

FIG. 7 illustrates a schematic top plan view of an embodiment of alignment electrodes and light emitting elements disposed within an opening defined by the bank pattern of FIG. 6.

FIG. 7 is a drawing for explaining some components included in the pixels PXL1 to PXL3 based on the bank BNK of FIG. 5A and the bank patterns BNP1 to BNP4 of FIG. 5B.

Referring to FIG. 7, the alignment electrodes ALE1 to ALE9, the bank patterns BNP1 to BNP4, and the bank BNK may be sequentially disposed along the third direction DR3.

In one or more embodiments, the first to ninth alignment electrodes ALE1 to ALE9 may be electrodes for aligning the first to third light emitting elements LD1 to LD3.

In one or more embodiments, the first to third alignment electrodes ALE1 to ALE3 may be disposed to be spaced from each other in the first direction DR1, and may extend in the second direction DR2.

Referring to FIG. 5A, FIG. 5B, and FIG. 7, the first to third alignment electrodes ALE1 to ALE3 may be exposed through the first opening OP1 of the first bank pattern BNP1. In one or more embodiments, the first to third alignment electrodes ALE1 to ALE3 corresponding to the first sub-pixel SPX1 may be exposed through the (1-1)-th opening OP1-1. The first to third alignment electrodes ALE1 to ALE3 corresponding to the second sub-pixel SPX2 may be exposed through the (1-2)-th opening OP1-2. The first to third alignment electrodes ALE1 to ALE3 corresponding to the third sub-pixel SPX3 may be exposed through the (1-3)-th opening OP1-3. In one or more embodiments, the first to third alignment electrodes ALE1 to ALE3 may overlap the first horizontal extension HBNK1 of the bank BNK in a plan view.

In one or more embodiments, the fourth to sixth alignment electrodes ALE4 to ALE6 may be disposed to be spaced from the first to third alignment electrodes ALE1 to ALE3 in the second direction DR2, and the fourth to sixth alignment electrodes ALE4 to ALE6 may be sequentially disposed to be spaced from each other in the first direction DR1, and may extend in the second direction DR2.

Referring to FIG. 5A, FIG. 5B, and FIG. 7, the fourth to sixth alignment electrodes ALE4 to ALE6 may be exposed through the second opening OP2 of the second bank pattern BNP2. In one or more embodiments, the fourth to sixth alignment electrodes ALE4 to ALE6 corresponding to the first sub-pixel SPX1 may be exposed through the (2-1)-th opening OP2-1. The fourth to sixth alignment electrodes ALE4 to ALE6 corresponding to the second sub-pixel SPX2 may be exposed through the (2-2)-th opening OP2-2. The fourth to sixth alignment electrodes ALE4 to ALE6 corresponding to the third sub-pixel SPX3 may be exposed through the (2-3)-th opening OP2-3. In one or more embodiments, the fourth to sixth alignment electrodes ALE4 to ALE6 may extend from the first light emitting area EMA1 to the second light emitting area EMA2. The fourth to sixth alignment electrodes ALE4 to ALE6 may overlap the second horizontal extension HBNK2 of the bank BNK in a plan view.

In one or more embodiments, the seventh to ninth alignment electrodes ALE7 to ALE9 may be disposed to be spaced apart from the fourth to sixth alignment electrodes ALE4 to ALE6 in the second direction DR2, and the seventh to ninth alignment electrodes ALE7 to ALE9 may be sequentially disposed to be spaced from each other in the first direction DR1, and may extend in the second direction DR2. In one or more embodiments, the seventh to ninth alignment electrodes ALE7 to ALE9 may be disposed under the third bank pattern BNP3.

Referring to FIG. 5A, FIG. 5B, and FIG. 7, the seventh to ninth alignment electrodes ALE7 to ALE9 may be exposed through the third opening OP3 of the third bank pattern BNP3. In one or more embodiments, the seventh to ninth alignment electrodes ALE7 to ALE9 corresponding to the first sub-pixel SPX1 may be exposed through the (3-1)-th opening OP3-1. The seventh to ninth alignment electrodes ALE7 to ALE9 corresponding to the second sub-pixel SPX2 may be exposed through the (3-2)-th opening OP3-2. The seventh to ninth alignment electrodes ALE7 to ALE9 corresponding to the third sub-pixel SPX3 may be exposed through the (3-3)-th opening OP3-3. In one or more embodiments, the seventh to ninth alignment electrodes ALE7 to ALE9 may extend from the second emission area EMA2 to the third emission area EMA3. The seventh to ninth alignment electrodes ALE7 to ALE9 may overlap the third horizontal extension HBNK3 of the bank BNK in a plan view.

In one or more embodiments, the bank BNK may form a space that may accommodate a fluid. For example, ink including the light emitting elements LD1 to LD3 may be provided in the space during the manufacturing process. The space may correspond to the first to third light emitting areas EMA1 to EMA3 of the first to third pixels PXL1 to PXL3. The light emitting elements LD1 to LD3 may be disposed in the first to third light emitting areas EMA1 to EMA3, and may be disposed on the first to ninth alignment electrodes ALE1 to ALE9. The first light emitting element LD1 may be disposed in the first light emitting area EMA1, the second light emitting element LD2 may be disposed in the second light emitting area EMA2, and the third light emitting element LD3 may be disposed in the third light emitting area EMA3.

In one or more embodiments, the first to ninth alignment electrodes ALE1 to ALE9 may receive a first alignment signal or a second alignment signal that is different from the first alignment signal in a process step (hereinafter, referred to as an alignment process) in which the first to third light emitting elements LD1 to LD3 are aligned.

In one or more embodiments, the first alignment signal and the second alignment signal may have different waveforms, potentials, and/or phases. The first alignment signal may be a ground signal, and the second alignment signal may be an AC signal. However, the present disclosure is not necessarily limited to the example described above. For example, the first alignment signal may be an AC signal, and the second alignment signal may be a ground signal.

In one or more embodiments, the first alignment signal may be applied to the first, third, fifth, seventh, and ninth alignment electrodes ALE1, ALE3, ALE5, ALE7, and ALE9. The second alignment signal may be applied to the second, fourth, sixth, and eighth alignment electrodes ALE2, ALE4, ALE6, and ALE8.

In one or more embodiments, the first, third, fifth, seventh, and ninth alignment electrodes ALE1, ALE3, ALE5, ALE7, and ALE9 may be connected to the lower first power line PL1 through the first contact portion CNT1. In the alignment process, the first alignment signal may be provided to the first, third, fifth, seventh, and ninth alignment electrodes ALE1, ALE3, ALE5, ALE7, and ALE9 through the first power line PL1.

In one or more embodiments, the second, fourth, sixth, and eighth alignment electrodes ALE2, ALE4, ALE6, and ALE8 may be connected to the lower second power line PL2 through the second contact portion CNT2. In the alignment process, the second alignment signal may be provided to the second, fourth, sixth, and eighth alignment electrodes ALE2, ALE4, ALE6, and ALE8 through the second power line PL2.

In one or more embodiments, the second alignment electrode ALE2 may be integrally provided (and/or formed) with the fourth alignment electrode ALE4 and the sixth alignment electrode ALE6. The second, fourth, and sixth alignment electrodes ALE2, ALE4, and ALE6 may be physically and electrically connected through the first bridge electrode BRE1a. For example, the (1-1)-th bridge electrode BRE1a may be disposed between the first bank pattern BNP1 and the second bank pattern BNP2. The first alignment signal may be applied to the second, fourth, and sixth alignment electrodes ALE2, ALE4, and ALE6 through the second contact portion CNT2 connected to the (1-1)-th bridge electrode BRE1a.

In one or more embodiments, the first and third alignment electrodes ALE1 and ALE3 may be integrally formed through the (2-1)-th bridge electrode BRE2a. In one or more embodiments, the fifth alignment electrode ALE5 may be integrally provided (and/or formed) with the seventh alignment electrode ALE7 and the ninth alignment electrode ALE9. The fifth, seventh, and ninth alignment electrodes ALE5, ALE7, and ALE9 may be physically and electrically connected through the (2-1)-th bridge electrode BRE2a. For example, the (2-1)-th bridge electrode BRE2a connected to the fifth, seventh, and ninth alignment electrodes ALE5, ALE7, and ALE9 may be disposed between the second bank pattern BNP2 and the third bank pattern BNP3. For example, the second alignment signal may be applied to the first, third, fifth, seventh, and ninth alignment electrodes ALE1, ALE3, ALE5, ALE7, and ALE9 through the first contact portion CNT1 connected to the (2-1)-th bridge pattern BRE2a.

In one or more embodiments, the (1-1)-th bridge electrode BRE1a and the (2-1)-th bridge electrode BRE2a may overlap the first to third light emitting areas EMA1 to EMA3 in a plan view. In an example, the (1-1)-th bridge electrode BRE1a may overlap the first and third light emitting areas EMA1 and EMA3 of the first and third pixels PXL1 and PXL3. The (2-1)-th bridge electrode BRE2a may overlap the second light emitting area EMA2.

In one or more embodiments, an electric field may be formed between (or on) the first to ninth alignment electrodes ALE1 to ALE9, and the light emitting elements LD1 to LD3 disposed between the first to ninth alignment electrodes ALE1 to ALE9 may be moved (or rotated) by a force (for example, a dielectroporesis (DEP) force) according to the electric field to be aligned (or disposed) on the alignment electrode.

In one or more embodiments, the light emitting elements LD aligned (e.g., disposed) at the lower end portions of the first to third alignment electrodes ALE1 to ALE3 with respect to the first horizontal extension HBNK1 from among the light emitting elements LD disposed between the first to third alignment electrodes ALE1 to ALE3 may configure the first light emitting elements LD1 of the first pixel PXL1.

In one or more embodiments, the light emitting elements LD aligned (e.g., disposed) at the upper end portions of the fourth to sixth alignment electrodes ALE4 to ALE6 with respect to the second horizontal extension HBNK2 from among the light emitting elements LD disposed between the fourth to sixth alignment electrodes ALE4 to ALE6 may configure the first light emitting elements LD1 of the first pixel PXL1.

In one or more embodiments, the light emitting elements LD aligned (e.g., disposed) at the lower end portions of the fourth to sixth alignment electrodes ALE4 to ALE6 with respect to the second horizontal extension HBNK2 from among the light emitting elements LD disposed between the fourth to sixth alignment electrodes ALE4 to ALE6 may configure the second light emitting elements LD2 of the second pixel PXL2.

In one or more embodiments, the light emitting elements LD aligned (e.g., disposed) at the upper end portions of the seventh to ninth alignment electrodes ALE7 to ALE9 with respect to the third horizontal extension HBNK3 from among the light emitting elements LD disposed between the seventh to ninth alignment electrodes ALE7 to ALE9 may configure the second light emitting elements LD2 of the second pixel PXL2.

In one or more embodiments, the light emitting elements LD aligned (e.g., disposed) at the lower end portions of the seventh to ninth alignment electrodes ALE7 to ALE9 with respect to the third horizontal extension HBNK3 from among the light emitting elements LD disposed between the seventh to ninth alignment electrodes ALE7 to ALE9 may configure the third light emitting elements LD3 of the third pixel PXL3.

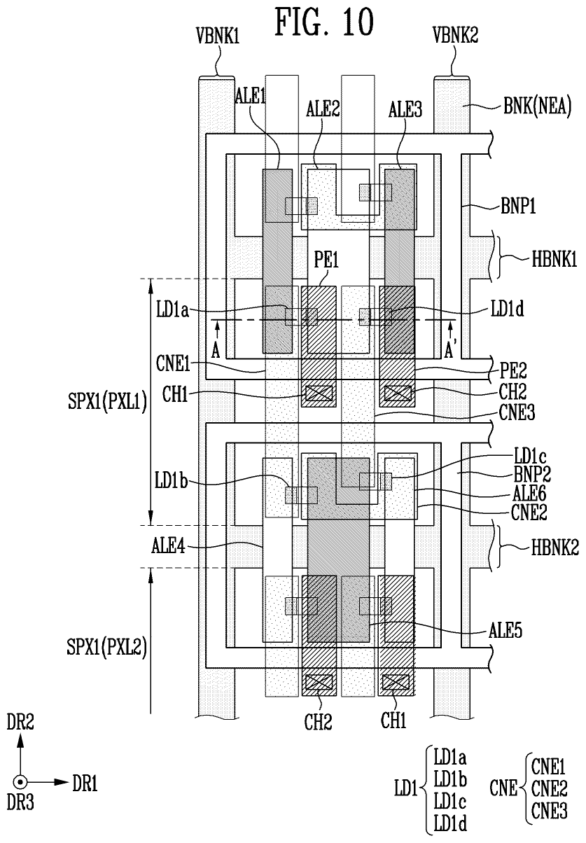

In one or more embodiments, the first end portion (for example, the first end portion EP1 of the light emitting element LD in FIG. 3 and FIG. 4) of the light emitting element (for example, the (1-1)-th and (1-4)-th light emitting elements LD1a and LD1d of FIG. 10) disposed between the first to third alignment electrodes ALE1 to ALE3 of the first light emitting elements LD1 may be disposed adjacent to the second alignment electrode ALE2.

In one or more embodiments, the second end portion (for example, the second end portion EP2 of the light emitting element LD in FIG. 3 and FIG. 4) of the light emitting element (for example, the (1-2)-th and (1-3)-th light emitting elements LD1b and LD1c of FIG. 10) disposed between the fourth to sixth alignment electrodes ALE4 to ALE6 of the first light emitting elements LD1 may be disposed adjacent to the fifth alignment electrode ALE5. In an example, the second end portion EP2 of the light emitting element disposed between the fourth to sixth alignment electrodes ALE4 to ALE6 from among the second light emitting elements LD2 may also be disposed adjacent to the fifth alignment electrode ALE5.

In one or more embodiments, the first end portion EP1 of the light emitting element disposed between the seventh to ninth alignment electrodes ALE7 to ALE9 of the second light emitting elements LD2 may be disposed adjacent to the eighth alignment electrode ALE8.

In one or more embodiments, the first pixel PXL1 may include first to third sub-pixels SPX1 to SPX3 spaced from each other in the first direction DR1. In an example, the first and third alignment electrodes ALE1 and ALE3 disposed in the first sub-pixel SPX1 of the corresponding pixel may be electrically connected to the first and third alignment electrodes ALE1 and ALE3 disposed in the adjacent second sub-pixel SPX2 of the corresponding pixel.

In one or more embodiments, the first and third alignment electrodes ALE1 and ALE3 disposed in the first sub-pixel SPX1 may be physically and/or electrically connected to the first and third alignment electrodes ALE1 and ALE3 disposed in the second sub-pixel SPX2. For example, the first and third alignment electrodes ALE1 and ALE3 disposed in the first sub-pixel SPX1 may be connected to the first and third alignment electrodes ALE1 and ALE3 disposed in the second sub-pixel SPX2 through the (2-2)-th bridge electrode BRE2b.

In one or more embodiments, the first and third alignment electrodes ALE1 and ALE3 disposed in the first sub-pixel SPX1 may be physically and/or electrically connected to the first and third alignment electrodes ALE1 and ALE3 disposed in the second sub-pixel SPX2. Accordingly, even if a contact defect occurs in the first contact portion CNT1 disposed in the first sub-pixel SPX1, the first alignment signal may be applied to the first and third alignment electrodes ALE1 and ALE3 disposed in the first sub-pixel SPX1 through the first contact portion CNT1 disposed in the second sub-pixel SPX2.

In one or more embodiments, the fourth and sixth alignment electrodes ALE4 and ALE6 disposed in the first sub-pixel SPX1 may be physically and/or electrically connected to the fourth and sixth alignment electrodes ALE4 and ALE6 disposed in the second sub-pixel SPX2. For example, the fourth and sixth alignment electrodes ALE4 and ALE6 disposed in the first sub-pixel SPX1 may be connected to the fourth and sixth alignment electrodes ALE4 and ALE6 disposed in the second sub-pixel SPX2 through the (1-2)-th bridge electrode BRE1b.

In one or more embodiments, the fourth and sixth alignment electrodes ALE4 and ALE6 disposed in the first sub-pixel SPX1 may be physically and/or electrically connected to the fourth and sixth alignment electrodes ALE4 and ALE6 disposed in the second sub-pixel SPX2. Accordingly, even if a contact defect occurs in the second contact portion CNT2 disposed in the first sub-pixel SPX1, the second alignment signal may be applied to the fourth and sixth alignment electrodes ALE4 and ALE6 disposed in the first sub-pixel SPX1 through the second contact portion CNT2 disposed in the second sub-pixel SPX2.

In one or more embodiments, the seventh to ninth alignment electrodes ALE7 to ALE9 may have the same structure and shape as the first to third alignment electrodes ALE1 to ALE3.

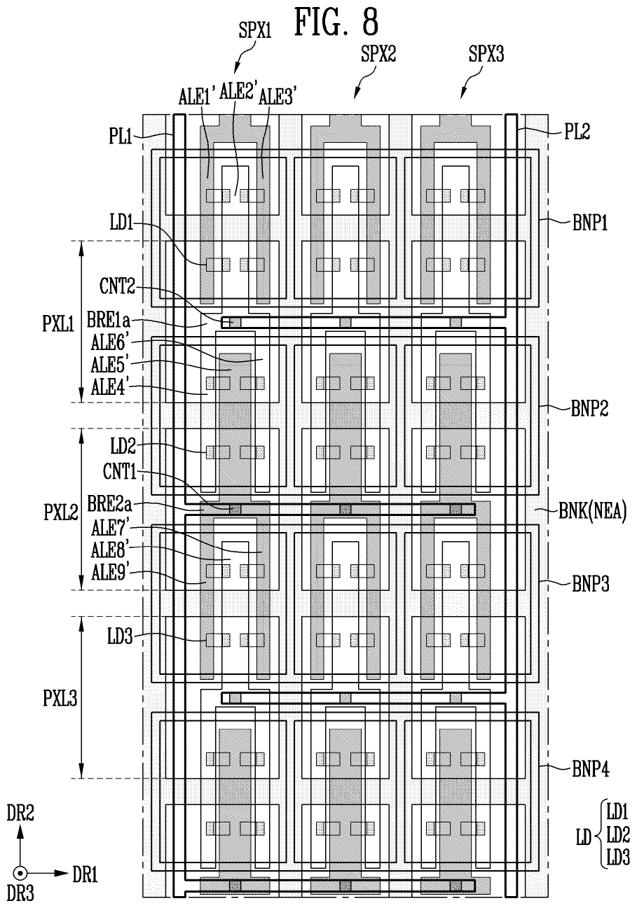

FIG. 8 illustrates a schematic top plan view of another embodiment of alignment electrodes and light emitting elements disposed within an opening defined by the bank pattern of FIG. 6.

In components except for first to ninth alignment electrodes ALE1′ to ALE9′, redundant descriptions of components that are the same as or correspond to those shown in FIG. 7 will be omitted.

Referring to FIG. 8, alignment electrodes ALE1′ to ALE9′, the bank patterns BNP1 to BNP4, and the bank (BNK) may be sequentially disposed along the third direction DR3.

In one or more embodiments, the first pixel PXL1 may include first to third sub-pixels SPX1 to SPX3 that are spaced from each other in the first direction DR1.

For example, the first and third alignment electrodes ALE1′ and ALE3′ disposed in the first sub-pixel SPX1 may be physically separated from the first and third alignment electrodes ALE1′ and ALE3′ disposed in the second sub-pixel SPX2 adjacent to each other in the first direction DR1.

In one or more embodiments, the first and third alignment electrodes ALE1′ and ALE3′ disposed in the first sub-pixel SPX1 may be physically and/or electrically separated from the first and third alignment electrodes ALE1′ and ALE3′ disposed in the second sub-pixel SPX2. For example, the first alignment signal may be applied to the first and third alignment electrodes ALE1′ and ALE3′ disposed in the first sub-pixel SPX1 only through the first contact portion CNT1 disposed in the first sub-pixel SPX1.

In one or more embodiments, the fourth and sixth alignment electrodes ALE4′ and ALE6′ disposed in the first sub-pixel SPX1 may be physically and/or electrically separated from the fourth and sixth alignment electrodes ALE4′ and ALE6′ disposed in the second sub-pixel SPX2. For example, the second alignment signal may be applied to the fourth and sixth alignment electrodes ALE4′ and ALE6′ disposed in the first sub-pixel SPX1 only through the second contact portion CNT2 disposed in the first sub-pixel SPX1.

In one or more embodiments, the seventh to ninth alignment electrodes ALE7′ to ALE9′ may have the same structure and shape as the first to third alignment electrodes ALE1′ to ALE3′.

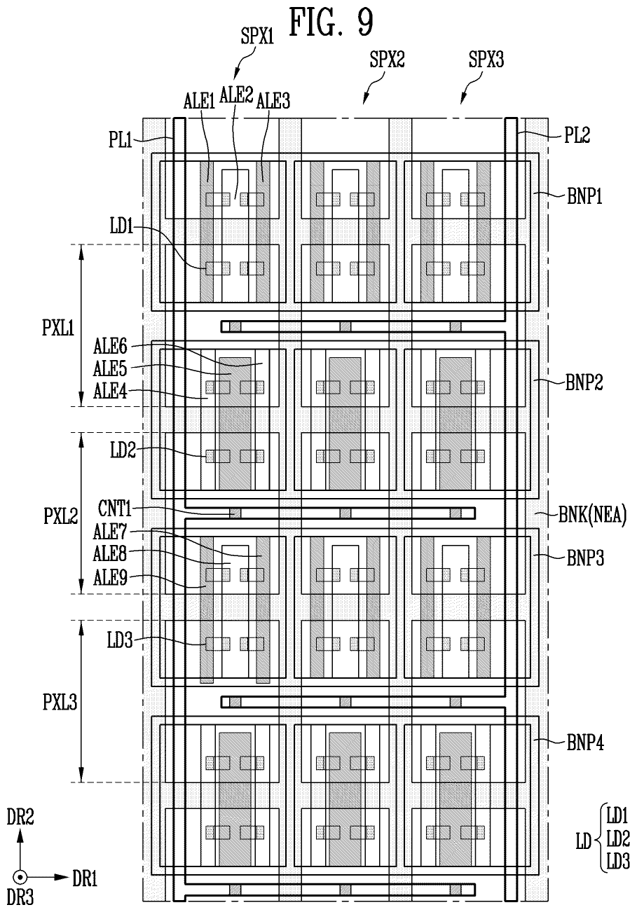

FIG. 9 illustrates a schematic top plan view of another embodiment of alignment electrodes and light emitting elements disposed within an opening defined by the bank pattern of FIG. 6.

Referring to FIG. 7 to FIG. 9, a portion of the (2-1)-th bridge electrode BRE2a may be removed around the first contact portion CNT1 after the alignment process of the first to third light emitting elements LD1 to LD3 is completed, thereby disconnecting the electrical connection between the first, third, fifth, seventh, and ninth alignment electrodes ALE1, ALE3, ALE5, ALE7, and ALE9 and the first power line PL1. In an example, a portion of the (1-1)-th bridge electrode BRE1a may be removed around the second contact portion CNT2 after the alignment process of the first to third light emitting elements LD1 to LD3 is completed, thereby disconnecting the electrical connection between the second, fourth, sixth, and eighth alignment electrodes ALE2, ALE4, ALE6, and ALE8 and the second power line PL2.

In one or more embodiments, after the alignment process of the first to third light emitting elements LD1 to LD3 is completed, the first to ninth alignment electrodes ALE1 to ALE9 may be in a floating state.

Referring to FIG. 7 and FIG. 9, the fourth and sixth alignment electrodes ALE4 and ALE6 around the (1-2)-th bridge electrode BRE1b after the alignment process of the first to third light emitting elements LD1 to LD3 is completed may be removed. Accordingly, the fourth and sixth alignment electrodes ALE4 and ALE6 disposed in the first sub-pixel SPX1 may be electrically separated from the fourth and sixth alignment electrodes ALE4 and ALE6 disposed in the second sub-pixel SPX2. In another example, the fourth and sixth alignment electrodes ALE4 and ALE6 around the (1-2)-th bridge electrode BRE1b after the alignment process of the first to third light emitting elements LD1 to LD3 is completed may not be removed. In this case, the fourth and sixth alignment electrodes ALE4 and ALE6 disposed in the first sub-pixel SPX1 may be electrically connected to the fourth and sixth alignment electrodes ALE4 and ALE6 disposed in the second sub-pixel SPX2.

Referring to FIG. 7 and FIG. 9, the first and third alignment electrodes ALE1 and ALE3 around the (2-2)-th bridge electrode BRE2b after the alignment process of the first to third light emitting elements LD1 to LD3 is completed may be removed. Accordingly, the first and third alignment electrodes ALE1 and ALE3 disposed in the first sub-pixel SPX1 may be electrically separated from the first and third alignment electrodes ALE1 and ALE3 disposed in the second sub-pixel SPX2. In another example, the first and third alignment electrodes ALE1 and ALE3 around the (2-2)-th bridge electrode BRE2b after the alignment process of the first to third light emitting elements LD1 to LD3 is completed may not be removed. In this case, the first and third alignment electrodes ALE1 and ALE3 disposed in the first sub-pixel SPX1 may be electrically connected to the first and third alignment electrodes ALE1 and ALE3 disposed in the second sub-pixel SPX2.

FIG. 10 illustrates a schematic top plan view of an embodiment of a sub-pixel included in the display device of FIG. 1.

FIG. 10 is a diagram for explaining some components included in the first sub-pixel SPX1 of the first pixel PXL1 based on the bank BNK and the first and second bank patterns BNP1 and BNP2 of FIG. 9.

The second pixel PXL2 and the third pixel PXL3 are substantially the same as the first pixel PXL1, so the first pixel PXL1 will be mainly described. The second sub-pixel SPX2 and the third sub-pixel SPX3 are substantially the same as the first sub-pixel SPX1, so the first sub-pixel SPX1 will be mainly described.

Referring to FIG. 10, the first sub-pixel SPX1 of the first pixel PXL1 included in the display device may include a first light emitting element LD1, alignment electrodes ALE1 to ALE6, pixel electrodes PE1 and PE2, and connection electrodes CNE1 to CNE3.

Referring to FIG. 10, the first sub-pixel SPX1 of the first pixel PXL1 may be provided with the first light emitting element LD1 in a (1-1)-th light emitting area (for example, the (1-1)-th light emitting area EMA1-1 of FIG. 5A) partitioned by the bank BNK.

In one or more embodiments, the first light emitting element LD1 may include a (1-1)-th light emitting element LD1a, a (1-2)-th light emitting element LD1b, a (1-3)-th light emitting element LD1c, and a (1-4)-th light emitting element LD1d.

In one or more embodiments, the (1-1)-th light emitting element LD1a and the (1-4)-th light emitting element LD1d may be disposed on lower end portions of the first to third alignment electrodes ALE1 to ALE3 with respect to the first horizontal extension HBNK1. In an example, an electric field is formed between (or on) the first alignment electrode ALE1 and the second alignment electrode ALE2, and the (1-1)-th light emitting element LD1a may be aligned on the first alignment electrode ALE1 and the second alignment electrode ALE2 based on the electric field. In an example, an electric field is formed between (or on) the second alignment electrode ALE2 and the third alignment electrode ALE3, and the (1-4)-th light emitting element LD1d may be aligned on the second alignment electrode ALE2 and the third alignment electrode ALE3 based on the electric field.

In one or more embodiments, the first end portion of the (1-1)-th light emitting element LD1a and the first end portion of the (1-4)-th light emitting element LD1d may be adjacent to the second alignment electrode ALE2. The first end portion of the (1-1)-th light emitting element LD1a and the first end portion of the (1-4)-th light emitting element LD1d may be disposed to face each other. In an example, the second end portion of the (1-1)-th light emitting element LD1a may be adjacent to the first alignment electrode ALE1. The second end portion of the (1-4)-th light emitting element LD1d may be adjacent to the third alignment electrode ALE3.

In one or more embodiments, the (1-2)-th light emitting element LD1b and the (1-3)-th light emitting element LD1c may be disposed on the upper end portions of the fourth to sixth alignment electrodes ALE4 to ALE6 with respect to the second horizontal extension HBNK2. In an example, an electric field is formed between (or on) the fourth alignment electrode ALE4 and the fifth alignment electrode ALE5, and the (1-2)-th light emitting element LD1b may be aligned on the fourth alignment electrode ALE4 and the fifth alignment electrode ALE5 based on the electric field. In an example, an electric field is formed between (or on) the fifth alignment electrode ALE5 and the sixth alignment electrode ALE6, and the (1-3)-th light emitting element LD1c may be aligned on the fifth alignment electrode ALE5 and the sixth alignment electrode ALE6 based on the electric field.

In one or more embodiments, the second end portion of the (1-2)-th light emitting element LD1b and the second end portion of the (1-3)-th light emitting element LD1c may be adjacent to the fifth alignment electrode ALE5. The second end portion of the (1-2)-th light emitting element LD1b and the second end portion of the (1-3)-th light emitting element LD1c may be disposed to face each other. In an example, the first end portion of the (1-2)-th light emitting element LD1b may be adjacent to the fourth alignment electrode ALE4. The first end portion of the (1-3)-th light emitting element LD1c may be adjacent to the sixth alignment electrode ALE6.

In the process in which the first light emitting elements LD1 are aligned, the first light emitting elements LD1 may not be aligned in the center of the alignment electrodes ALE1 to ALE6 but may be biased to one side thereof by the waveform of the alignment signal, the surface state and material of the bank patterns BNP1 and BNP1, and the asymmetry of the electric field formed between the alignment electrodes. For example, in the process of aligning the (1-1)-th light emitting element LD1a, the (1-1)-th light emitting element LD1a may be slightly biased to the first alignment electrode ALE1. That is, the first end portion of the (1-1)-th light emitting element LD1a may be disposed at the end of the second alignment electrode ALE2.

In this case, as the ratio of light emitting elements disposed with a bias toward one alignment electrode from among the first light emitting elements LD in the (1-1)-th light emitting area increases, the light emitting efficiency of the corresponding sub-pixel may decrease. The positions of the first and second pixel electrodes PE1 and PE2 (or connection electrodes CNE) may be controlled to improve or minimize contact defects of the first light emitting element LD1 biased to one side of the alignment electrodes.

Referring to FIG. 10, the first sub-pixel SPX1 of the first pixel PXL1 may include a first pixel electrode PE1, a second pixel electrode PE2, and connection electrodes CNE.

In one or more embodiments, the first and second pixel electrodes PE1 and PE2 and the connecting electrodes CNE may be disposed on the first to sixth alignment electrodes ALE1 to ALE6.

In one or more embodiments, the first pixel electrode PE1 may overlap a portion of the second alignment electrode ALE2. The first pixel electrode PE1 may overlap the first end portion of the (1-1)-th light emitting element LD1a. In an example, the first pixel electrode PE1 may be electrically connected to a first power line (for example, the first power line PL1 of FIG. 2) of a pixel circuit (for example, the pixel circuit PXC of FIG. 2) through a first contact hole CH1. In an example, the first pixel electrode PE1 may be connected to the first driving power source VDD through the first power line PL1.

In one or more embodiments, the second pixel electrode PE2 may overlap a portion of the third alignment electrode ALE3. The second pixel electrode PE2 may overlap the second end portion of the (1-4)-th light emitting element LD1d. In an example, the second pixel electrode PE2 may be electrically connected to the second power line (for example, the second power line PL2 of FIG. 2) of the pixel circuit PXC through the second contact hole CH2. In an example, the second pixel electrode PE2 may be connected to the second driving power source VSS through the second power line PL2.

In one or more embodiments, the first pixel electrode PE1 may be electrically connected to the second pixel electrode PE2 through the connection electrodes CNE.

In one or more embodiments, the connection electrodes CNE may include a first connection electrode CNE1, a second connection electrode CNE2, and a third connection electrode CNE3.

In one or more embodiments, the first connection electrode CNE1 and the third connection electrode CNE3 may have a bar shape. For example, the first connection electrode CNE1 and the third connection electrode CNE3 may be spaced from each other in the first direction DR1, and may extend in the second direction DR2.

In one or more embodiments, the second connection electrode CNE2 may have a shape bent at least once or more. The second connection electrode CNE2 may be spaced from the first connection electrode CNE1 in the first direction DR1, and may have a shape bent to surround the third connection electrode CNE3.

In one or more embodiments, the first connection electrode CNE1 may overlap a portion of the first alignment electrode ALE1, and may extend in the second direction DR2 to overlap a portion of the fourth alignment electrode ALE4. The first connection electrode CNE1 may overlap the second end portion of the (1-1)-th light emitting element LD1a and the first end portion of the (1-2)-th light emitting element LD1b.

In one or more embodiments, the first connection electrode CNE1 may be disposed across the first bank pattern BNP1 and the second bank pattern BNP2.

In one or more embodiments, the second connection electrode CNE2 may overlap the fifth alignment electrode ALE5 and the sixth alignment electrodes ALE6. The second connection electrode CNE2 may overlap the second end portion of the (1-2)-th light emitting element LD1b and the first end portion of the (1-3)-th light emitting element LD1c. In a plan view, the second connection electrode CNE2 may overlap the second bank pattern BNP2, and may not overlap the first bank pattern BNP1.

In one or more embodiments, the third connection electrode CNE3 may overlap a portion of the second alignment electrode ALE2, and may extend in the second direction DR2 to overlap a portion of the fifth alignment electrode ALE5. The third connection electrode CNE3 may overlap the second end portion of the (1-3)-th light emitting element LD1c and the first end portion of the ((1-4)-th light emitting element LD1d.

In one or more embodiments, the third connection electrode CNE3 may be disposed across the first bank pattern BNP1 and the second bank pattern BNP2.

In one or more embodiments, the (1-1)-th light emitting element LD1a may be connected between the first pixel electrode PE1 and the first connection electrode CNE1 to configure the first serial stage SET1 of the light emitting portion (for example, the light emitting portion EMU of FIG. 2). The first end portion of the (1-1)-th light emitting element LD1a may be connected to the first pixel electrode PE1, and the second end portion of the (1-1)-th light emitting element LD1a may be connected to the first connection electrode CNE1.

In one or more embodiments, the (1-2)-th light emitting element LD1b may be connected between the first connection electrode CNE1 and the second connection electrode CNE2 to configure the second serial stage SET2 of the light emitting portion (for example, the light emitting portion EMU of FIG. 2). The first end portion of the (1-2)-th light emitting element LD1b may be connected to the first connection electrode CNE1, and the second end portion of the (1-2)-th light emitting element LD1b may be connected to the second connection electrode CNE2.

In one or more embodiments, the (1-3)-th light emitting element LD1c may be connected between the second connection electrode CNE2 and the third connection electrode CNE3 to configure the third serial stage SET3 of the light emitting portion (for example, the light emitting portion EMU of FIG. 2). The first end portion of the (1-3)-th light emitting element LD1c may be connected to the second connection electrode CNE2, and the second end portion of the (1-3)-th light emitting element LD1c may be connected to the third connection electrode CNE3.

In one or more embodiments, the (1-4)-th light emitting element LD1d may be connected between the third connection electrode CNE3 and the second pixel electrode PE2 to configure the fourth serial stage SET4 of the light emitting portion (for example, the light emitting portion EMU of FIG. 2). The first end portion of the (1-4)-th light emitting element LD1d may be connected to the third connection electrode CNE3, and the second end portion of the (1-4)-th light emitting element LD1d may be connected to the second pixel electrode PE2.

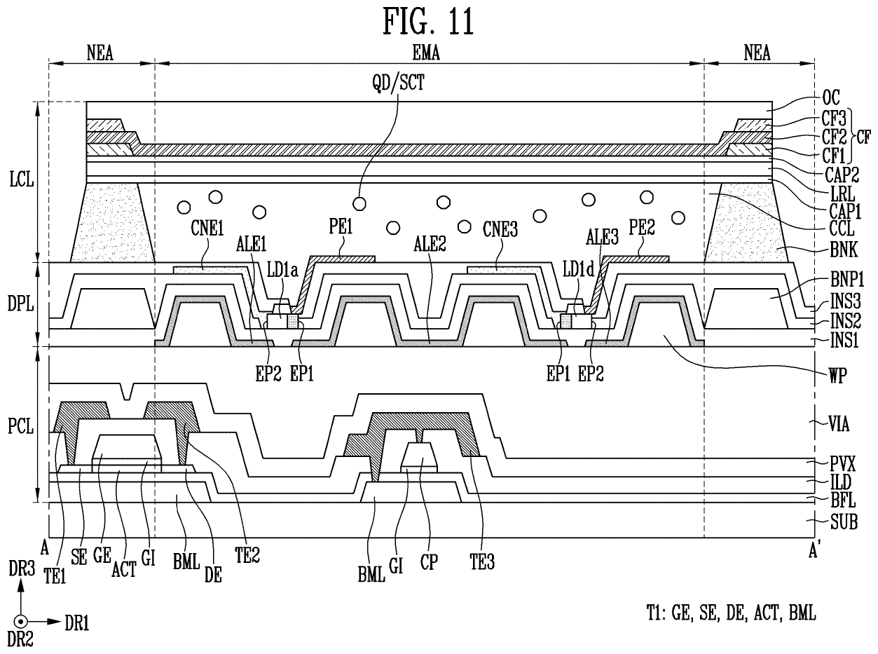

FIG. 11 illustrates a schematic cross-sectional view of an example taken along the line A-A′ of FIG. 10.

The sub-pixel SPX may include a substrate SUB, a pixel circuit layer PCL, a display element layer DPL, and a light conversion layer LCL. The pixel circuit layer PCL, the display element layer DPL, and the light conversion layer LCL may be sequentially disposed on the substrate SUB.

In FIG. 11, a first transistor (for example, the first transistor T1 of FIG. 2) is illustrated as an example of circuit elements that may be disposed in the pixel circuit layer PCL.

The pixel circuit layer PCL may include a first transistor T1, and a plurality of insulating layers BFL, GI, ILD, PVX, and VIA. The first transistor T1 may include a lower metal layer BML, a semiconductor pattern ACT, a gate electrode GE, a source electrode SE (or a first transistor electrode TE1) and a drain electrode DE (or a second transistor electrode TE2).

A conductive layer may be disposed between the substrate SUB and the buffer layer BFL. The first conductive layer may include a conductive material. The conductive material may include at least one of various metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and/or the like, and/or an alloy thereof. The first conductive layer may be configured as a single film, a double film, or a multi-film.

The first conductive layer may include the lower metal layer BML, the first power line PL1, and the second power line PL2. The lower metal layer BML and the gate electrode GE of the first transistor T1 may overlap each other with the buffer layer BFL, the semiconductor pattern ACT, and the gate insulating layer GI interposed therebetween. The lower metal layer BML may be disposed below the semiconductor pattern ACT of the first transistor T1. In this case, the lower metal layer BML may function as a light blocking pattern to stabilize the operation characteristics of the first transistor T1.

In one or more embodiments, the first transistor T1 may not include the lower metal layer BML. In this case, the buffer layer BFL may be directly disposed on the substrate SUB. In addition, the lower metal layer BML may be physically and/or electrically connected to the source electrode SE of the first transistor T1, which will be described later, through a contact hole in the buffer layer BFL. Accordingly, the threshold voltage of the first transistor T1 may be moved in a negative direction or a positive direction.

The buffer layer BFL covers the lower metal layer BML, and may be disposed on the substrate SUB. The buffer layer BFL may prevent impurities from spreading into the pixel circuit layer PCL. The buffer layer BFL may include an inorganic material. For example, the inorganic material may include at least one of metal oxides such as a silicon nitride (SiNx), a silicon oxide (SiOx), a silicon oxynitride (SiOxNy), and/or an aluminum oxide (AlOx). The buffer layer BFL may be omitted depending on the material, and process condition, and the like of the substrate SUB.

The semiconductor pattern ACT may be disposed on the buffer layer BFL. The semiconductor pattern ACT may include a first region (for example, a source region) connected to the source electrode SE, a second region (for example, a drain region) connected to the drain electrode DE, and a channel region between the first and second regions. The channel region may overlap the gate electrode GE of the first transistor T1 in the third direction DR3. The semiconductor pattern ACT may be a semiconductor pattern made of a poly silicon, an amorphous silicon, an oxide semiconductor, and/or the like.

The gate insulating layer GI may be disposed on the semiconductor pattern ACT. The gate insulating layer GI may be partially disposed only on the semiconductor pattern ACT, or may be disposed entirely on the substrate SUB. The gate insulating layer GI may include an inorganic material. However, it is not limited thereto, and the gate insulating layer GI may include an organic material. For example, the organic material may include at least one of an acrylic resin, an epoxy resin, a phenolic resin, a polyamide resin, a polyimide resin, an unsaturated polyester resin, a poly-phenylene ether resin, a poly-phenylene sulfide resin, and/or a benzocyclobutene resin.

A second conductive layer may be disposed on the gate insulating layer GI. The second conductive layer may include a conductive material similar to the first conductive layer. The second conductive layer may include a gate electrode GE and a contact pattern CP.

The gate electrode GE may be disposed on the gate insulating layer GI to overlap the channel region of the semiconductor pattern ACT in the third direction DR3. In one or more embodiments, the contact pattern CP may overlap the second power line PL2.

The interlayer insulating layer ILD may cover the second conductive layer and may be disposed entirely on the substrate SUB. The interlayer insulating layer ILD may include an inorganic material, similar to the gate insulating layer GI. The interlayer insulating layer ILD may include an organic material.

A third conductive layer may be disposed on the interlayer insulating layer ILD. The third conductive layer may include a conductive material similar to the first conductive layer. The third conductive layer may include first to third transistor electrodes TE1 to TE3.

The first transistor electrode TE1 may contact or may be connected to the source electrode SE of the semiconductor pattern ACT through a contact hole penetrating the interlayer insulating layer ILD, and in one or more embodiments, may also contact or may be connected to the lower metal layer BML through a contact hole penetrating the interlayer insulating layer ILD and the buffer layer BFL. The second transistor electrode TE2 may contact or may be connected to the drain electrode DE of the semiconductor pattern ACT through a contact hole penetrating the interlayer insulating layer ILD. The third transistor electrode TE3 may contact or may be connected to the bottom metal layer BML. In one or more embodiments, the third transistor electrode TE3 may contact or may be connected to the second power line PL2.

The passivation layer PVX may be disposed entirely on the substrate SUB to cover the third conductive layer. The passivation layer PVX may include an inorganic material. The passivation layer PVX may be provided as a single film, or may be provided as a multifilm of at least two or more films. In one or more embodiments, the passivation layer PVX may be omitted. The via layer VIA may include an organic material. The via layer VIA may provide a flat surface thereon. The passivation layer PVX may protect the first transistor T1 and the first to third transistor electrodes TE1 to TE3 disposed under the passivation layer PVX.

The display element layer DPL may be disposed on the via layer VIA.

The display element layer DPL may include wall patterns WP, first to third alignment electrodes ALE1 to ALE3 (or alignment electrodes, reflective electrodes), a first bank pattern BNP1, light emitting elements LD1a and LD1d, first and second pixel electrodes PE1 and PE2, first and third connection electrodes CNE1 and CNE3, and a plurality of insulating layers INS1 to INS3.

The wall patterns WP may be disposed on the via layer VIA. Each of the wall patterns WP may have a cross-section of a trapezoidal shape of which width is narrowed from one surface (for example, an upper surface) of the via layer VIA toward an upper portion thereof along the third direction DR3. In one or more embodiments, each of the wall patterns WP may include a curved surface having a cross section of a semi-elliptic shape or a semi-circular shape (or semi-spherical shape) of which width is narrowed from one surface of the via layer VIA toward an upper portion thereof along the third direction DR3. When viewed in a cross-sectional view, the shape of each of the wall patterns WP is not limited to the above-described embodiments, and the shape thereof may be variously changed within a range in which the first bank may improve efficiency of light emitted from each of the light emitting elements LD1a and LD1d.

The wall patterns WP include an inorganic material and/or an organic material, and may be configured of a single film or a multi-film. In one or more embodiments, the wall patterns WP may be omitted. For example, a structure corresponding to the wall patterns WP may be formed in the via layer VIA.

The first to third alignment electrodes ALE1 to ALE3 may be disposed on the via layer VIA and the wall patterns WP. The first to third alignment electrodes ALE1 to ALE3 may be disposed on the wall patterns WP. When viewed in a cross-sectional view, the first to third alignment electrodes ALE1 to ALE3 may have surface profiles respectively corresponding to the shapes of the wall patterns WP.

Each of the first to third alignment electrodes ALE1 to ALE3 may include a conductive material having a constant reflectivity to allow light emitted from the light emitting elements LD1a and LD1d to be directed in an image display direction (for example, the third direction DR3) of the display device. The first to third alignment electrodes ALE1 to ALE3 may be configured as a single film or multi-film.

The first to third electrodes ALE1 to ALE3 may be used as alignment electrodes for aligning the light emitting elements LD1a and LD1d in a manufacturing process of a display device.

The first insulating layer INS1 may be disposed on the via layer VIA to cover at least a portion of the first to third alignment electrodes ALE1 to ALE3. The first insulating layer INS1 is disposed between the first to third alignment electrodes ALE1 to ALE3, and may prevent a short circuit between the first alignment electrode ALE1 and the second alignment electrode ALE2, and between the second alignment electrode ALE2 and the third alignment electrode ALE3. The first insulating layer INS1 may include an organic material and/or an inorganic material.

The light emitting elements LD1a and LD1d may be disposed on the first insulating layer INS1.

In one or more embodiments, the (1-1)-th light emitting element LD1a may be aligned between the first alignment electrode ALE1 and the second alignment electrode ALE2 so that the first end portion EP1 of the (1-1)-th light emitting element LD1a faces the second alignment electrode ALE2 and the second end portion EP2 of the (1-1)-th light emitting element LD1a faces the first alignment electrode ALE1. In one or more embodiments, the first end portion EP1 of the (1-1)-th light emitting element LD1a may partially overlap the second alignment electrode ALE2 in the third direction DR3, and the second end portion EP2 of the (1-1)-th light emitting element LD1a may partially overlap the first alignment electrode ALE1 in the third direction DR3. However, the present disclosure is not limited thereto. In another example, the first end portion EP1 of the (1-1)-th light emitting element LD1a may partially overlap the second alignment electrode ALE2 in the third direction DR3, and the second end portion EP2 of the (1-1)-th light emitting element LD1a may not overlap the first alignment electrode ALE1 in the third direction DR3. That is, the (1-1)-th light emitting element LD1a may be disposed closer to the second alignment electrode ALE2.

In one or more embodiments, the (1-4)-th light emitting element LD1d may be aligned between the second alignment electrode ALE2 and the third alignment electrode ALE3 so that the first end portion EP1 of the (1-4)-th light emitting element LD1d faces the second alignment electrode ALE2 and the second end portion EP2 of the (1-4)-th light emitting element LD1d faces the third alignment electrode ALE3. In another example, the first end portion EP1 of the (1-4)-th light emitting element LD1d may partially overlap the second alignment electrode ALE2 in the third direction DR3, and the second end portion EP2 of the (1-4)-th light emitting element LD1d may not overlap the third alignment electrode ALE3 in the third direction DR3. That is, the (1-4)-th light emitting element LD1d may be disposed closer to the second alignment electrode ALE2.

The first bank pattern BNP1 may be disposed on the first insulating layer INS1. The first bank pattern BNP1 may define the area in which the first to third alignment electrodes ALE1 to ALE3 are exposed. The first bank pattern BNP1 may include an organic material. In one or more embodiments, the first bank pattern BNP1 may include a light blocking material and/or a reflective material.

The second insulating layer INS2 (or the second insulating pattern) may be disposed on the light emitting elements LD1a and LD1d. The second insulating layer INS2 may be disposed on portions of the upper surfaces of the light emitting elements LD1a and LD1d such that the first and second end portions EP1 and EP2 of the light emitting elements LD1a and LD1d are exposed to the outside. In one or more embodiments, the second insulating layer INS2 may also be disposed on the first insulating layer INS1 and the first bank pattern BNP1.

The second insulating layer INS2 may include an inorganic material and/or an organic material according to the design conditions of the display device including the light emitting elements LD1a and LD1d. After the alignment of the light emitting elements LD1a and LD1d on the first insulating layer INS1 is completed, the second insulating layer INS2 is disposed on the light emitting elements LD1a and LD1d, thereby preventing the light emitting elements LD1a and LD1d from being separated from the aligned position. When there is a gap (or space) between the first insulating layer INS1 and the light emitting elements LD1a and LD1d before the second insulating layer INS2 is formed, the gap may be filled with the second insulating layer INS2 in the process of forming the second insulating layer INS2.

In one or more embodiments, the first connection electrode CNE1, the first pixel electrode PE1, the third connection electrode CNE3, and the second pixel electrode PE2 may be spaced from each other in the first direction DR1.

In one or more embodiments, the first and third connection electrodes CNE1 and CNE3 may be disposed on the second insulating layer INS2. In an example, the first connection electrode CNE1 may be disposed on the first alignment electrode ALE1. The first connection electrode CNE1 may be in direct contact with the second end portion EP2 of the (1-1)-th light emitting element LD1a. In an example, the third connection electrode CNE3 may be disposed on the second alignment electrode ALE2. The third connection electrode CNE3 may be in direct contact with the first end portion EP1 of the (1-4)-th light emitting element LD1d.

In one or more embodiments, the third insulating layer INS3 may be disposed on the second insulating layer INS2 and the first and third connection electrodes CNE1 and CNE3 to cover the second insulating layer INS2 and the first and third connection electrodes CNE1 and CNE3. The third insulating layer INS3 may be disposed so that the first end portion EP1 of the (1-1)-th light emitting element LD1a and the second end portion EP2 of the (1-4)-th light emitting element LD1d are exposed and so that one end and an edge of the second insulating layer INS2 directly contact each other. The third insulating layer INS3 may include an inorganic material.

In one or more embodiments, the first and second pixel electrodes PE1 and PE2 may be disposed on the third insulating layer INS3. The first pixel electrode PE1 may be in direct contact with the first end portion EP1 of the (1-1)-th light emitting element LD1a. In an example, the second pixel electrode PE2 may be disposed on the third alignment electrode ALE3. The second pixel electrode PE2 may be in direct contact with the second end portion EP2 of the (1-4)-th light emitting element LD1d.

The first pixel electrode PE1 may be in contact with or connected to the source electrode SE of the first transistor T1 through a contact hole penetrating the first to third insulating layers INS1 to INS3, the via layer VIA, and the passivation layer PVX. That is, the first pixel electrode PE1 may electrically connect the first end portion EP1 of the (1-1)-th light emitting element LD1a to the source electrode SE of the first transistor T1 via the first transistor electrode TE1.

The second pixel electrode PE2 may contact or connect a contact hole penetrating the first to third insulating layers INS1 to INS3, the via layer VIA, and the passivation layer PVX to the contact pattern CP. That is, the second pixel electrode PE2 may electrically connect the second end portion EP2 of the (1-4)-th light emitting element LD1d to the second power line PL2.

Although FIG. 11 illustrates that the first and second pixel electrodes PE1 and PE2 and the first and third connection electrodes CNE1 and CNE3 are disposed on different layers with the third insulating layer INS3 interposed therebetween, the present disclosure is not limited thereto. For example, the first and second pixel electrodes PE1 and PE2 may be disposed on (e.g., at) the same layer (for example, the second insulating layer INS2) through the same process.

The light conversion layer LCL may be disposed on the display element layer DPL.

The light conversion layer LCL may further include a bank BNK, a color conversion layer CCL, and color filters CF.

The bank BNK may be disposed on the display element layer DPL. The bank BNK may have a trapezoidal cross-section in which the width of the bank BNK decreases from one surface (for example, an upper surface) toward the upper portion along the third direction DR3. In one or more embodiments, the bank BNK may include a curved surface having a cross section of a semi-elliptic shape or a semi-circular shape (or semi-spherical shape) of which width is narrowed from one surface of the third insulating layer INS3 toward an upper portion thereof along the third direction DR3. When viewed in a cross-sectional view, the shape of the bank BNK is not limited to the above-described embodiments, and the shape thereof may be variously changed within a range in which the first bank may improve efficiency of light emitted from each of the light emitting elements LD.

In the step of supplying the light emitting elements LD1a and LD1d, the bank BNK may be a dam structure that prevents a solution including the light emitting elements LD1a and LD1d from flowing into adjacent pixels (and/or sub-pixels) or controls a certain amount of solution to be supplied to each pixel. In addition, the bank BNK may define the light emitting area EMA.

The bank BNK may include an organic material. In one or more embodiments, the bank BNK may include a light blocking material and/or a reflective material. In this case, the bank BNK may prevent a light leakage defect in which light leaks between the pixel PXL and pixels adjacent thereto. For example, the bank BNK may include a color filter material or a black matrix material. As another example, a reflective material layer may be separately provided and/or formed on the bank BNK to further improve the efficiency of light emitted from the pixel to the outside.

The color conversion layer CCL may be disposed on the display element layer DPL (or the light emitting elements LD1a, LD1d) within an area surrounded by the bank BNK.

The color conversion layer CCL may include color conversion particles QD (or wavelength conversion particles) corresponding to a specific color. As an example, the color conversion layer CCL may include color conversion particles QD that convert light of a first color (or a first wavelength band) incident from the light emitting element LD into light of a second color (or a specific color or a second wavelength band) and emit the light.

When the sub-pixel is a red pixel (or a red sub-pixel), the sub-pixel SPX may include color conversion particles of a red quantum dot that converts light of a first color emitted from the light emitting elements LD1a and LD1d into light of a second color (for example, red light).

When the sub-pixel is a green pixel (or a green sub-pixel), the sub-pixel SPX may include color conversion particles of a green quantum dot that converts light of a first color emitted from the light emitting elements LD1a and LD1d into light of a second color (for example, green light).

When the sub-pixel is a blue pixel (or a blue sub-pixel), the sub-pixel may include color conversion particles of a blue quantum dot that converts light of a first color emitted from the light emitting elements LD1a and LD1d into light of a third color (for example, blue light). When the sub-pixel SPX is a blue pixel and the light emitting elements LD1a and LD1d emit blue-based light, the sub-pixel SPX may include a light scattering layer including light scattering particles SCT. The above-described light scattering layer may be omitted according to one or more embodiments. According to another embodiment, when the sub-pixel SPX is a blue pixel, a transparent polymer may be provided instead of the color conversion layer CCL.

A first capping layer CAP1 may seal (or cover) the color conversion layer CCL. The first capping layer CAP1 may be disposed between a low refractive index layer LRL and the color conversion layer CCL. The first capping layer CAP1 may prevent impurities such as moisture or air from penetrating from the outside. For example, the first capping layer CAP1 may include one or more selected from among a silicon nitride (SiNx), a silicon oxide (SiOx), a silicon oxynitride (SiOxNy), and/or an aluminum oxide (AlOx).

The low refractive index layer LRL may be disposed between the first capping layer CAP1 and a second capping layer CAP2. The low refractive index layer LRL may improve light efficiency by recycling light provided from the color conversion layer CCL. To this end, the low refractive index layer LRL may have a lower refractive index than the color conversion layer CCL. In one or more embodiments, the low refractive index layer LRL may include a base resin and hollow particles dispersed within the base resin. The hollow particles may include hollow silica particles. In addition, the hollow particle may be a pore formed by a porogen, but is not necessarily limited thereto. In addition, the low refractive index layer LRL may include one or more selected from among a zinc oxide (ZnOx), a titanium oxide (TiOx), and/or a nano silicate particle, but is not necessarily limited thereto.

In one or more embodiments, a second capping layer CAP2 may be disposed on the low refractive index layer LRL. The second capping layer CAP2 may prevent impurities such as moisture or air from penetrating from the outside. The second capping layer CAP2 may include one or more selected from among a silicon nitride (SiNx), a silicon oxide (SiOx), a silicon oxynitride (SiOxNy), and/or an aluminum oxide (AlOx).

In one or more embodiments, the color filters CF may be disposed on the second capping layer CAP2. The color filter layer may include a first color filter CF1, a second color filter CF2, and a third color filter CF3.

In one or more embodiments, each of the first to third color filters CF1 to CF3 may include a color filter material selectively transmitting light of a specific color converted in the color conversion layer CCL. For example, the first color filter CF1 may be a red color filter, the second color filter CF2 may be a green color filter, and the third color filter CF3 may be a blue color filter. Although FIG. 11 illustrates that the second color filter CF2 is disposed on the color conversion layer CCL of the sub-pixel SPX, when the sub-pixel SPX is a red pixel, the first color filter CF1 may be disposed on the color conversion layer CCL. When the sub-pixel SPX is a blue pixel, the third color filter CFL3 may be disposed.

The first to third color filters CF1 to CF3 may be disposed to overlap each other in the bank BNK, thereby blocking light interference between adjacent sub-pixels. In one or more embodiments, a separate light blocking pattern may be disposed in the non-light emitting area NEA instead of the stack structure of the first to third color filters CF1 to CF3.

An overcoat layer OC may be disposed on the color filters CF. The overcoat layer OC may include an inorganic material and/or an organic material.

The overcoat layer OC may block water or moisture from flowing into the color filters CF and the display element layer DPL from the outside by entirely covering components positioned thereunder. In one or more embodiments, the overcoat layer OC may be formed of multiple layers. For example, the overcoat layer OC may include at least two layers of inorganic films and at least one layer of organic film interposed between the at least two layers of inorganic films. However, the material and/or structure of the overcoat layer OC may be variously changed. In the above-described embodiment, it has been described that the color conversion layer CCL is directly formed on the display element layer DPL, but the present disclosure is not limited thereto. In one or more embodiments, the color conversion layer CCL may be formed on a separate substrate to be coupled to the display element layer DPL through an adhesive material. For example, the adhesive material may be an optical clear adhesive layer, but is not limited thereto.

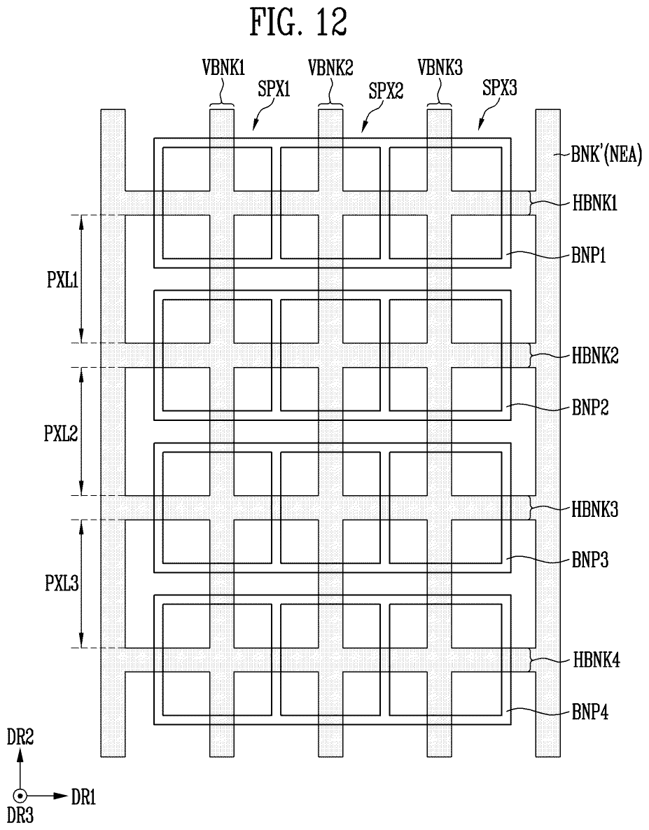

FIG. 12 illustrates a schematic top plan view of another embodiment of a disposition relationship between the bank of FIG. 5A and the bank pattern of FIG. 5B.

Referring to FIG. 5A, FIG. 5B, and FIG. 12, a bank BNK′ may overlap the bank patterns BNP1 to BNP4 in a plan view. In an example, the first light emitting area EMA1 (for example, the light emitting area of the first pixel PXL1) of the bank BNK′ may overlap the lower end portion of the first bank pattern BNP1 and the upper end portion of the second bank pattern BNP2 in a plan view. In an example, the second light emitting area EMA2 (for example, the light emitting area of the second pixel PXL2) of the bank BNK′ may overlap the lower end portion of the second bank pattern BNP2 and the upper end portion of the third bank pattern BNP3 in a plan view. In an example, the third light emitting area EMA3 (for example, the light emitting area of the third pixel PXL3) of the bank BNK′ may overlap the lower end portion of the third bank pattern BNP3 and the upper end portion of the fourth bank pattern BNP4 in a plan view.

Referring to FIG. 5A, FIG. 5B, and FIG. 12, the 1-1 light emitting area EMA1-1, which is the light emitting area of the first sub-pixel SPX1 of the first pixel PXL, may overlap the (1-1)-th opening OP1-1 and the (1-2)-th opening OP1-2 of the first bank pattern BNP1, and the (2-1)-th opening OP2-1 and the (2-2)-th opening OP2-2 of the second bank pattern BNP2. In an example, the upper end portion of the (1-1)-th light emitting area EMA1-1 may overlap the right side of the lower end portion of the (1-1)-th opening OP1-1 and the left side of the lower end portion of the (1-2)-th opening OP1-2. The lower end portion of the (1-1)-th light emitting area EMA1-1 may overlap the right side of the upper end portion of the (2-1)-th opening OP2-1 and the left side of the upper end portion of the (2-2)-th opening OP2-2.

In one or more embodiments, the first vertical extension VBNK1 and the first horizontal extension portion HBNK1 of the bank BNK′ may cross the (1-1)-th opening OP1-1 of the first bank pattern BNP1. The second vertical extension VBNK2 and the first horizontal extension HBNK1 of the bank BNK′ may cross the (1-2)-th opening OP1-2 of the first bank pattern BNP1. The third vertical extension VBNK3 and the first horizontal extension HBNK1 of the bank BNK′ may cross the (1-3)-th opening OP1-3 of the first bank pattern BNP1.

In one or more embodiments, the first vertical extension VBNK1 and the second horizontal extension HBNK2 of the bank BNK′ may cross the (2-1)-th opening OP2-1 of the second bank pattern BNP2. The second vertical extension VBNK2 and the second horizontal extension HBNK2 of the bank BNK′ may cross the (2-2)-th opening OP2-2 of the second bank pattern BNP2. The third vertical extension VBNK3 and the second horizontal extension HBNK2 of the bank BNK′ may cross the (2-3)-th opening OP2-3 of the second bank pattern BNP2.

In one or more embodiments, the first vertical extension VBNK1 and the third horizontal extension HBNK3 of the bank BNK′ may cross the (3-1)-th opening OP3-1 of the third bank pattern BNP3. The second vertical extension VBNK2 and the third horizontal extension HBNK3 of the bank BNK′ may cross the (3-2)-th opening OP3-2 of the third bank pattern BNP3. The third vertical extension VBNK3 and the third horizontal extension HBNK3 of the bank BNK′ may cross the (3-3)-th opening OP3-3 of the third bank pattern BNP3.

FIG. 13 illustrates a schematic top plan view of an embodiment of alignment electrodes and light emitting elements disposed within an opening defined by the bank pattern of FIG. 12.

FIG. 13 is a drawing for explaining some components included in the pixels PXL1 to PXL3 based on the bank BNK′ and the bank patterns BNP1 to BNP4 of FIG. 12.

Referring to FIG. 13, alignment electrodes ALE1″ to ALE12″, the bank patterns BNP1 to BNP4, and the bank (BNK) may be sequentially disposed in the third direction DR3.

In one or more embodiments, the first to twelfth alignment electrodes ALE1″ to ALE12″ may be electrodes for aligning the first and second light emitting elements LD1 and LD2.

In one or more embodiments, the first to sixth alignment electrodes ALE1″ to ALE6″ may be disposed to be spaced from each other in the first direction DR1, and may extend in the second direction DR2.

Referring to FIG. 5A, FIG. 5B, and FIG. 13, the first to third alignment electrodes ALE1″ to ALE3″ may be exposed through the (1-1)-th opening OP1-1 of the first bank pattern BNP1. The fourth to sixth alignment electrodes ALE4″ to ALE6″ may be exposed through the (1-2)-th opening OP1-2 of the first bank pattern BNP1.

In one or more embodiments, the seventh to twelfth alignment electrodes ALE7″ to ALE12″ may be spaced from the first to sixth alignment electrodes ALE1″ to ALE6″ in the second direction DR2, may be sequentially disposed and spaced from each other in the first direction DR1, and may extend in the second direction DR2.

Referring to FIG. 5A, FIG. 5B, and FIG. 13, the seventh to ninth alignment electrodes ALE7″ to ALE9″ may be exposed through the (2-1)-th opening OP2-1 of the second bank pattern BNP2. The tenth to twelfth alignment electrodes ALE10″ to ALE12″ may be exposed through the (2-2)-th opening OP2-2 of the second bank pattern BNP2.

In one or more embodiments, portions of the second to sixth alignment electrodes ALE2″ to ALE6″ exposed through the (1-1)-th opening OP1-1 and the (1-2)-th opening OP1-2 of the first bank pattern BNP1 may correspond to the first light emitting area EMA1.

In one or more embodiments, portions of the eighth to eleventh alignment electrodes ALE8″ to ALE11″ exposed through the (2-1)-th opening OP2-1 and the (2-2)-th opening OP2-2 of the second bank pattern BNP2 may correspond to the first light emitting area EMA1.

In one or more embodiments, a portion of the second alignment electrode ALE2″ and the third alignment electrode ALE3″ exposed through the (1-1)-th opening OP1-1 of the first bank pattern BNP1 may be disposed in an area corresponding to the first light emitting area EMA1 of the bank BNK.

In one or more embodiments, the fourth alignment electrode ALE4″ and a portion of the fifth alignment electrode ALE5″ exposed through the (1-2)-th opening OP1-2 of the first bank pattern BNP1 may be disposed in an area corresponding to the first light emitting area EMA1 of the bank BNK.

In one or more embodiments, a portion of the eighth alignment electrode ALE8″ and the ninth alignment electrode ALE9″ exposed through the (2-1)-th opening OP2-1 of the second bank pattern BNP2 may be disposed in an area corresponding to the first light emitting area EMA1 of the bank BNK.

In one or more embodiments, a portion of the tenth alignment electrode ALE10″ and the eleventh alignment electrode ALE11″ exposed through the (2-2)-th opening OP2-2 of the second bank pattern BNP2 may be disposed in an area corresponding to the first light emitting area EMA1 of the bank BNK.

In one or more embodiments, the first to twelfth alignment electrodes ALE1″ to ALE12″ may be supplied (e.g., provided) with a first alignment signal or a second alignment signal different from the first alignment signal in a process step (hereinafter, referred to as an alignment process) in which the first and second light emitting elements LD1 and LD2 are aligned, respectively.

In one or more embodiments, the first alignment signal may be applied to the first, third, fourth, sixth, eighth, and eleventh alignment electrodes ALE1″, ALE3″, ALE4″, ALE6″, ALE8″, and ALE11″. The second alignment signal may be applied to the second, fifth, seventh, ninth, tenth, and twelfth alignment electrodes ALE2″, ALE5″, ALE7″, ALE9″, ALE10″, and ALE12″.

In one or more embodiments, an electric field is formed between (or on) the first to twelfth alignment electrodes ALE1″ to ALE12″, and the first and second light emitting elements LD1 and LD2 disposed between the first to twelfth alignment electrodes ALE1″ to ALE12″ may be moved by a force (for example, a dielectrophoresis (DEP) force) according to the electric field (or rotated) to be aligned (or disposed) on the alignment electrode.

In one or more embodiments, the light emitting elements LD aligned (e.g., disposed) at lower end portions of the second to fifth alignment electrodes ALE2″ to ALE5″ with respect to the first horizontal extension HBNK1 may configure the first light emitting elements LD1 of the first sub-pixel SPX1 of the first pixel PXL1. In one or more embodiments, the light emitting elements LD aligned (e.g., disposed) at the upper end portions of the eighth to eleventh alignment electrodes ALE8″ to ALE11″ with respect to the second horizontal extension HBNK2 may configure the first light emitting elements LD1 of the first sub-pixel SPX1 of the first pixel PXL1.

In one or more embodiments, the light emitting elements LD aligned (disposed) at lower end portions of the eighth to eleventh alignment electrodes ALE8″ to ALE11″ with respect to the second horizontal extension HBNK2 may configure the second light emitting elements LD2 of the first sub-pixel SPX1 of the second pixel PXL1.

In one or more embodiments, the eighth to eleventh alignment electrodes ALE8″ to ALE11″ may extend from the first light emitting area EMA1 in the second direction DR2 to be disposed in the second light emitting area EMA2. In an example, the first sub-pixel SPX1 of the first pixel PXL1 may share the eighth to eleventh alignment electrodes ALE8″ to ALE11″ with the first sub-pixel SPX1 of the second pixel PXL2.

In one or more embodiments, the third pixel PXL3 may have the same disposition structure as the first pixel PXL1. In an example, the first to sixth alignment electrodes ALE1″ to ALE6″ may be exposed through the (3-1)-th opening OP3-1 and the (3-2)-th opening OP3-2 of the third bank pattern BNP3.

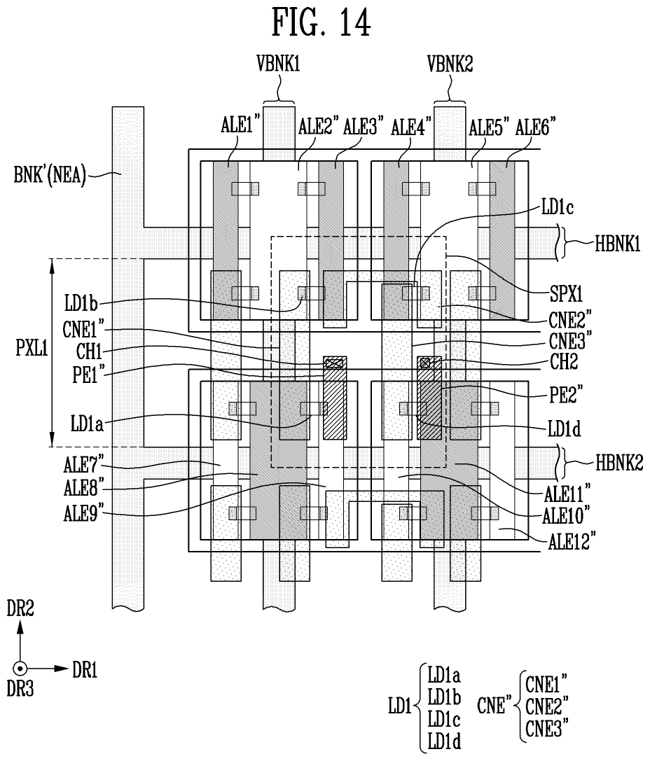

FIG. 14 illustrates a schematic top plan view of another embodiment of a sub-pixel included in the display device of FIG. 1.

FIG. 14 is a diagram for explaining some components included in the first sub-pixel SPX1 of the first pixel PXL1 based on the bank BNK′ and the first and second bank patterns BNP1 and BNP2 of FIG. 13.

The second pixel PXL2 and the third pixel PXL3 are substantially the same as the first pixel PXL1, so the first pixel PXL1 will be mainly described. The second sub-pixel SPX2 and the third sub-pixel SPX3 are substantially the same as the first sub-pixel SPX1, so the first sub-pixel SPX1 will be mainly described.

Referring to FIG. 14, the first sub-pixel SPX1 of the first pixel PXL1 included in the display device may include a first light emitting element LD1, alignment electrodes ALE2″ to ALE5″ and ALE8″ to ALE11″, first and second pixel electrodes PE1″ and PE2″, and connection electrodes CNE″.

Referring to FIG. 14, the first sub-pixel SPX1 of the first pixel PXL1 may be provided with the first light emitting element LD1 in a (1-1)-th light emitting area (for example, the (1-1)-th light emitting area EMA1-1 of FIG. 5A) partitioned by the bank BNK.

In one or more embodiments, the first light emitting element LD1 may include a (1-1)-th light emitting element LD1a, a (1-2)-th light emitting element LD1b, a (1-3)-th light emitting element LD1c, and a (1-4)-th light emitting element LD1d.

In one or more embodiments, the (1-1)-th light emitting element LD1a and the (1-4)-th light emitting element LD1d may be disposed on the upper end portions of the eighth to eleventh alignment electrodes ALE8″ to ALE11″ with respect to the second horizontal extension HBNK2. In an example, an electric field is formed between (or on) the eighth alignment electrode ALE8″ and the ninth alignment electrodes ALE9″, and the (1-1)-th light emitting element LD1a may be aligned on the eighth alignment electrode ALE8″ and the ninth alignment electrode ALE9″ based on the electric field. The first end portion of the (1-1)-th light emitting element LD1a may be disposed adjacent to the ninth alignment electrode ALE9″, and the second end portion of the (1-1)-th light emitting element LD1a may be disposed adjacent to the eighth alignment electrode ALE8″. In an example, an electric field may be formed between (or on) the tenth alignment electrode ALE10″ and the eleventh alignment electrodes ALE11″, and the (1-4)-th light emitting element LD1d may be aligned on the tenth alignment electrode ALE10″ and the eleventh alignment electrode ALE11″ based on the electric field. The first end portion of the (1-4)-th light emitting element LD1d may be disposed adjacent to the tenth alignment electrode ALE10″, and the second end portion of the (1-4)-th light emitting element LD1d may be disposed adjacent to the eleventh alignment electrode ALE11″.

In one or more embodiments, the (1-2)-th light emitting element LD1b and the (1-3)-th light emitting element LD1c may be disposed on the lower end portions of the second to fifth alignment electrodes ALE2″ to ALE5″ with respect to the first horizontal extension HBNK1. In an example, an electric field is formed between (or on) the second alignment electrode ALE2″ and the third alignment electrodes ALE3″, and the (1-2)-th light emitting element LD1b may be aligned on the second alignment electrode ALE2″ and the third alignment electrode ALE3″ based on the electric field.

The first end portion of the (1-2)-th light emitting element LD1b may be disposed adjacent to the second alignment electrode ALE2″, and the second end portion of the (1-2)-th light emitting element LD1b may be disposed adjacent to the third alignment electrode ALE3″. In an example, an electric field may be formed between (or on) the fourth alignment electrode ALE4″ and the fifth alignment electrodes ALE5″, and the (1-3)-th light emitting element LD1c may be aligned on the fourth alignment electrode ALE4″ and the fifth alignment electrode ALE5″ based on the electric field. The first end portion of the (1-3)-th light emitting element LD1c may be disposed adjacent to the fifth alignment electrode ALE5″, and the second end portion of the (1-3)-th light emitting element LD1c may be disposed adjacent to the fourth alignment electrode ALE4″.

Referring to FIG. 14, the first sub-pixel SPX1 of the first pixel PXL1 may include a first pixel electrode PE1″, a second pixel electrode PE2″, and connection electrodes CNE″.

In one or more embodiments, the first and second pixel electrodes PE1″ and PE2″ and the connection electrodes CNE″ may be disposed on the second to eleventh alignment electrodes ALE2″ to ALE11″.

In one or more embodiments, the first pixel electrode PE1″ may overlap the ninth alignment electrode ALE9″. The first pixel electrode PE1 may overlap the first end portion of the (1-1)-th light emitting element LD1a. In an example, the first pixel electrode PE1″ may be electrically connected to a first power line (for example, the first power line PL1 of FIG. 2) of a pixel circuit (for example, the pixel circuit PXC of FIG. 2) through a first contact hole CH1. In an example, the first pixel electrode PE1″ may be connected to the first driving power source VDD through the first power line PL1.

In one or more embodiments, the second pixel electrode PE2″ may overlap a portion of the eleventh alignment electrode ALE11″. The second pixel electrode PE2″ may overlap the second end portion of the (1-4)-th light emitting element LD1d. In an example, the second pixel electrode PE2″ may be electrically connected to the second power line (for example, the second power line PL2 of FIG. 2) of the pixel circuit PXC through the second contact hole CH2. In an example, the second pixel electrode PE2 may be connected to the second driving power source VSS through the second power line PL2.

In one or more embodiments, the first pixel electrode PE1″ may be electrically connected to the second pixel electrode PE2″ through the connection electrodes CNE″.

In one or more embodiments, the connection electrodes CNE″ may include a first connection electrode CNE1″, a second connection electrode CNE2″, and a third connection electrode CNE3″.

In one or more embodiments, the first connection electrode CNE1″ and the third connection electrode CNE3″ may have a bar shape. For example, the first connection electrode CNE1″ and the third connection electrode CNE3″ may be spaced from each other in the first direction DR1, and may extend in the second direction DR2.

In one or more embodiments, the second connection electrode CNE2″ may have a shape bent at least once or more. The second connection electrode CNE2″ may be spaced from the first connection electrode CNE1″ in the first direction DR1, and may have a shape bent to surround the third connection electrode CNE3″.

In one or more embodiments, the first connection electrode CNE1″ may overlap a portion of the second alignment electrode ALE2″, and may extend in the second direction DR2 to overlap a portion of the eighth alignment electrode ALE8″. The first connection electrode CNE1″ may overlap the second end portion of the (1-1)-th light emitting element LD1a and the first end portion of the (1-2)-th light emitting element LD1b.

In one or more embodiments, the first connection electrode CNE1″ may be disposed across the first bank pattern BNP1 and the second bank pattern BNP2.

In one or more embodiments, the second connection electrode CNE2″ may overlap the third alignment electrode ALE3″ and the fourth and fifth alignment electrodes ALE4″ and ALE5″. The second connection electrode CNE2″ may overlap the second end portion of the (1-2)-th light emitting element LD1b and the first end portion of the (1-3)-th light emitting element LD1c. In a plan view, the second connection electrode CNE2″ may overlap the first bank pattern BNP1, and may not overlap the second bank pattern BNP2.

In one or more embodiments, the third connection electrode CNE3″ may overlap a portion of the fourth alignment electrode ALE4″, and may extend in the second direction DR2 to overlap a portion of the tenth alignment electrode ALE10″. The third connection electrode CNE3″ may overlap the second end portion of the (1-3)-th light emitting element LD1c and the first end portion of the (1-4)-th light emitting element LD1d.

In one or more embodiments, the third connection electrode CNE3 may be disposed across the first bank pattern BNP1 and the second bank pattern BNP2.

In one or more embodiments, the (1-1)-th light emitting element LD1a may be connected between the first pixel electrode PE1″ and the first connection electrode CNE1″ to configure the first serial stage SET1 of the light emitting portion (for example, the light emitting portion EMU of FIG. 2). The first end portion of the (1-1)-th light emitting element LD1a may be connected to the first pixel electrode PE1″, and the second end portion of the (1-1)-th light emitting element LD1a may be connected to the first connection electrode CNE1″.

In one or more embodiments, the (1-2)-th light emitting element LD1b may be connected between the first connection electrode CNE1″ and the second connection electrode CNE2″ to configure the second serial stage SET2 of the light emitting portion (for example, the light emitting portion EMU of FIG. 2). The first end portion of the (1-2)-th light emitting element LD1b may be connected to the first connection electrode CNE1″, and the second end portion of the (1-2)-th light emitting element LD1b may be connected to the second connection electrode CNE2″.

In one or more embodiments, the (1-3)-th light emitting element LD1c may be connected between the second connection electrode CNE2″ and the third connection electrode CNE3″ to configure the third serial stage SET3 of the light emitting portion (for example, the light emitting portion EMU of FIG. 2). The first end portion of the (1-3)-th light emitting element LD1c may be connected to the second connection electrode CNE2″, and the second end portion of the (1-3)-th light emitting element LD1c may be connected to the third connection electrode CNE3″.

In one or more embodiments, the (1-4)-th light emitting element LD1d may be connected between the third connection electrode CNE3″ and the second pixel electrode PE2″ to configure the fourth serial stage SET4 of the light emitting portion (for example, the light emitting portion EMU of FIG. 2). The first end portion of the (1-4)-th light emitting element LD1d may be connected to the third connection electrode CNE3″, and the second end portion of the (1-4)-th light emitting element LD1d may be connected to the second pixel electrode PE2″.

The display device according to one or more embodiments of the present disclosure allows the alignment signal applied to the alignment electrodes disposed at the upper portion to be different from the alignment signal applied to the alignment electrodes disposed at the lower portion within the light emitting area EMA1 of one pixel, so that the alignment direction of the light emitting elements LD1a and LD1d disposed between the alignment electrodes disposed at the upper portion may be opposite to the alignment direction of the light emitting elements LD1b and LD1c disposed between the alignment electrodes disposed at the lower portion. Accordingly, the pixel electrode disposed on the light emitting element (for example, the first and third connection electrodes CNE1(CNE1″) and CNE3(CNE3″) in FIG. 10 or FIG. 14) may be disposed according to a position of the light emitting element biased to one side of the alignment electrodes to apply a signal to the light emitting element and concurrently (e.g., simultaneously) minimize (e.g., improve) contact defects due to the biased light emitting element.

While the present disclosure has been described in connection with what is presently considered to be practical embodiments, it is to be understood that the present disclosure is not limited to the embodiments disclosed herein, but, on the contrary, is intended to cover various modifications and equivalent arrangements included within the spirit and scope of the appended claims and their equivalents.

What is claimed is:

1. A display device comprising:
a first pixel including a first light emitting area at which first light emitting elements are located;
a second pixel spaced from the first light emitting area in a second direction and including a second light emitting area at which second light emitting elements are located; and
a bank partitioning the first light emitting area and the second light emitting area,
wherein the first pixel comprises:
a first alignment electrode, a second alignment electrode, and a third alignment electrode overlapping the first light emitting area and are sequentially located and spaced from each other in a first direction; and
a fourth alignment electrode, a fifth alignment electrode, and a sixth alignment electrode that are spaced from the first to third alignment electrodes in the second direction, and are sequentially located and spaced from each other in the first direction, and
wherein the fourth to sixth alignment electrodes extend in the second direction in the first light emitting area overlapping the second light emitting area.

2. The display device of claim 1, further comprising:
a first bank pattern including a first opening exposing the first to third alignment electrodes; and
a second bank pattern that is spaced from the first bank pattern in the second direction and includes a second opening exposing the fourth to sixth alignment electrodes.

3. The display device of claim 2, wherein
the second bank pattern overlaps one area of the first light emitting area and one area of the second light emitting area.

4. The display device of claim 2, wherein
the first to sixth alignment electrodes do not overlap the first bank pattern and the second bank pattern.

5. The display device of claim 2, wherein the first light emitting elements comprise:
a (1-1)-th light emitting element located between the first alignment electrode and the second alignment electrode;
a (1-2)-th light emitting element located between the fourth alignment electrode and the fifth alignment electrode;
a (1-3)-the light emitting element located between the fifth alignment electrode and the sixth alignment electrode; and
a (1-4)-th light emitting element located between the second alignment electrode and the third alignment electrode.

6. The display device of claim 5, wherein the first light emitting elements have been aligned in response to a first alignment signal supplied by the first alignment electrode, the third alignment electrode, and the fifth alignment electrode;
the second alignment electrode and the fourth alignment electrode are configured to supply a second alignment signal; and
the first alignment signal is different from the second alignment signal.

7. The display device of claim 5, wherein:
a first end portion of the (1-1)-th light emitting element and a first end portion of the (1-4) light emitting element are adjacent to the second alignment electrode; and
a second end portion of the (1-2)-th light emitting element and a second end portion of the (1-3)-th light emitting element are adjacent to the fifth alignment electrode.

8. The display device of claim 7, wherein the first pixel comprises:
a first pixel electrode electrically connected to a first driving power source and the first end portion of the (1-1)-th light emitting element;
a second pixel electrode spaced from the first pixel electrode and electrically connected to a second driving power source and a second end portion facing the first end portion of the (1-4)-th light emitting element; and
connection electrodes electrically connecting the first pixel electrode and the second pixel electrode.

9. The display device of claim 8, wherein the connection electrodes comprise:
a first connection electrode electrically connected to a second end portion of the (1-1)-th light emitting element and a first end portion of the (1-2)-th light emitting element;
a second connection electrode electrically connected to a second end portion of the (1-2)-th light emitting element and a first end portion of the (1-3)-th light emitting element; and
a third connection electrode electrically connected to a second end portion of the (1-3)-th light emitting element and a first end portion of the (1-4)-th light emitting element.

10. The display device of claim 9, wherein
the first connection electrode and the third connection electrode extend in the second direction from the first opening of the first bank pattern to the second opening of the second bank pattern.

11. The display device of claim 9, wherein
the second connection electrode does not overlap the first bank pattern and the second bank pattern.

12. The display device of claim 9, wherein
the second connection electrode overlaps the fifth alignment electrode and the sixth alignment electrode in a plan view.

13. The display device of claim 9, wherein
the first pixel electrode and the second pixel electrode extend between the first bank pattern and the second bank pattern in the first opening.

14. The display device of claim 13, wherein the first pixel comprises:
a first contact portion and a second contact portion located between the first bank pattern and the second bank pattern within the first light emitting area,
wherein the first pixel electrode is electrically connected to the first driving power source through the first contact portion, and
wherein the second pixel electrode is electrically connected to the second driving power source through the second contact portion.

15. The display device of claim 1, wherein the bank comprises:
a first vertical extension and a second vertical extension that are spaced from each other in the first direction and extend in the second direction; and
a first horizontal extension and a second horizontal extension that are spaced from each other in the second direction and extend in the first direction, and
wherein the first light emitting area corresponds to an area in which the first vertical extension, the second vertical extension, the first horizontal extension, and the second horizontal extension cross each other.

16. The display device of claim 15, wherein:
portions of the first to third alignment electrodes overlap the first horizontal extension in a plan view; and
portions of the fourth to sixth alignment electrodes overlap the second horizontal extension in a plan view.

17. A display device comprising:
a first pixel including a first light emitting area at which first light emitting elements are located;
a second pixel spaced from the first light emitting area in a second direction and including a second light emitting area at which second light emitting elements are located;
a bank partitioning the first light emitting area and the second light emitting area;
a first alignment electrode, a second alignment electrode, a third alignment electrode, a fourth alignment electrode, a fifth alignment electrode, and a sixth alignment electrode that are sequentially located and spaced from each other in a first direction; and
a seventh alignment electrode, an eighth alignment electrode, a ninth alignment electrode, a tenth alignment electrode, an eleventh alignment electrode, and a twelfth alignment electrode that are spaced from the first to sixth alignment electrodes in the second direction, and are sequentially located and spaced from each other in the first direction,
wherein the eighth to eleventh alignment electrodes extend in the second direction in the first light emitting area overlapping the second light emitting area.

18. The display device of claim 17, wherein the first light emitting elements comprise:
a (1-1)-th light emitting element located between the eighth alignment electrode and the ninth alignment electrode;
a (1-2)-th light emitting element located between the second alignment electrode and the third alignment electrode;
a (1-3)-th light emitting element located between the fourth alignment electrode and the fifth alignment electrode; and
a (1-4)-th light emitting element located between the tenth alignment electrode and the eleventh alignment electrode.

19. The display device of claim 17, further comprising:
a first bank pattern including a first opening exposing the first to sixth alignment electrodes; and
a second bank pattern that is spaced from the first bank pattern in the second direction and includes a second opening exposing the seventh to twelfth alignment electrodes.

20. The display device of claim 19, wherein:
the first opening includes a (1-1)-th opening exposing the first to third alignment electrodes and a (1-2)-th opening spaced from the (1-1)-th opening in the first direction and exposing the fourth to sixth alignment electrodes, and
the second opening includes a (2-1)-th opening exposing the seventh to ninth alignment electrodes and a (2-2)-th opening spaced from the (2-1)-th opening in the first direction and exposing the tenth to twelfth alignment electrodes.
